(19) United States
(12) Patent Application Publication
(10) Pub. No.: US 2022/0356372 A1
(43) Pub. Date: Nov. 10, 2022

(54) PREPARATION METHOD OF RECYCLED POLISHING AGENT SLURRY AND POLISHING AGENT SLURRY

(71) Applicant: Konica Minolta, Inc., Tokyo (JP)

(72) Inventors: Atsushi TAKAHASHI, Tokyo (JP); Akihiro MAEZAWA, Tokyo (JP); Fumiko TSUKIGATA, Tokyo (JP); Keisuke MIZOGUCHI, Tokyo (JP)

(21) Appl. No.: 17/658,574

(22) Filed: Apr. 8, 2022

(30) Foreign Application Priority Data
May 6, 2021 (JP) 2021-078740

(51) Int. Cl. C09G 1/02

(52) U.S. Cl. CPC C09G 1/02

(57) ABSTRACT

A recycled polishing agent slurry is prepared from a used polishing agent slurry after polishing a silicon material using a reference polishing agent slurry including a cerium oxide polishing agent and a dispersing agent. The preparation method includes: slurry collecting in which the used slurry discharged from a polishing machine is collected; separation and concentration in which the cerium oxide polishing agent in the collected slurry is separated from a component derived from the material to be polished and then concentrated, and polishing agent recycling in which a pH adjusting agent and the dispersing agent are added to the separated and concentrated cerium oxide polishing agent, and a recycled polishing agent slurry is adjusted to have a pH value at 25° C. of in a range of 6.0 to 10.5 and an electrical conductivity value in a range of 0.10 to 10.00 times that of the reference slurry.

### CROSS-REFERENCE TO RELATED APPLICATIONS

The entire disclosure of Japanese Patent Application No. 2021-078740 filed on May 6, 2021 is incorporated herein by reference in its entirety.

### BACKGROUND

### Technological Field

The present invention relates to a preparation method of a recycled polishing agent slurry and the polishing agent slurry, and more specifically, to a preparation method of a recycled polishing agent slurry and the polishing agent slurry causing less reduction in polishing speed and less scratches, burns, and the like.

### Description of Related Art

In the precise polishing process of glass and the chemical mechanical polishing (CMP) process in semiconductor manufacturing, rare earth oxides such as cerium oxide are used as polishing agents (also called “polishing materials” or “abrasive grains”). Polishing processes using cerium oxide as a polishing agent are carried out in the finishing processes of various products such optical glasses, cover glass of smartphones, and cover glass of automotive displays, as well as in the CMP processes of silicon oxide layers of semiconductors.

Cerium oxide is generally used in the following ways in the polishing process of glass or in the CMP process of semiconductors. A slurry of cerium oxide particles dispersed in water or the like is pressed against the glass with a polishing cloth or brush and is moved relative to the glass while pressure is applied, such that the polishing process is carried out.

In the CMP process, an excellent polishing performance is obtained due to chemical action that is induced, in addition to physical force, when abrasive grains come into contact with a material to be polished. Therefore, in the CMP process, it is important that the abrasive grains are stably dispersed in the slurry without agglomeration. In addition, when the abrasive grains in the polishing agent slurry agglomerate to form large particles, the polishing process is likely to cause scratches and other defects on the material to be polished. Therefore, it is also important to stably disperse the abrasive grains in the polishing agent slurry from the viewpoint of processing quality.

In recent years, higher and higher accuracy is required in the CMP process. For example, wiring in a semiconductor is becoming very fine and is just a few nm in width, and in addition, the wiring is becoming three-dimensional and multi-layered. Therefore, even minute scratches and defects of a few nm, which were conventionally permitted, would result in defective products. Thus, appropriate management of the polishing agent slurry is becoming more and more important.

Cerium oxide is commonly used in the CMP process of the material to be polished mainly composed of a silicon oxide. Since cerium oxide is unevenly produced in the world, and the process of extracting cerium oxide from minerals containing cerium oxide has a high environmental impact, it is strongly desired to use the precious resource effectively.

In order to effectively use cerium oxide, there is known a method of collecting and recycling the polishing agent from a cerium oxide polishing agent slurry that has been used in the CMP process. For example, Japanese Patent No. 6292119 discloses a polishing agent collection method in which a cerium oxide polishing agent is recycled from a used polishing agent slurry containing a cerium oxide polishing agent that has been used to polish a material whose main component is silicon. In the disclosed collection method of a cerium oxide polishing agent, specifically, an inorganic salt is added to the collected cerium oxide polishing agent slurry in a condition where pH of the mother liquid at 25° C. is 7 to 10, such that the polishing agent is agglomerated separately from the component derived from the polished material. The agglomerated polishing agent is separated from the mother liquid and concentrated, and then dispersed again by adding a dispersing agent.

In addition, Japanese Patent No. 5850192 and Japanese Patent No. 5843036 also disclose a collection method of a cerium oxide polishing agent from a used polishing agent slurry is also disclosed. More specifically, the method includes collecting a polishing agent from a polishing agent slurry that has been used to polish a material including silicon as a main component. In this method, a solvent is added without using a pH adjusting agent such that particles of a material that has been polished are dissolved, and then the polishing agent slurry is filtered to collect the polishing agent.

However, when the CMP process was carried out using the polishing agent slurry containing the polishing agent collected or recycled by the methods according to the above prior art documents, it was found that the polishing rate was reduced, and that scratches and burns (white cloudiness in the appearance of the polished materials, interference film, or the like) occurred.

### SUMMARY

The present invention has been made in view of the above problems and circumstances, to provide a preparation method of a recycled polishing agent slurry and the polishing agent slurry causing less reduction in polishing rate and less scratches, burns, and the like.

In order to solve the above problems, the inventors examined the causes of the above problems and speculated the followings. Because of the component of the polished material or ion component dissolving from the polished material, metal ion component mixed in during the process from use as a polishing agent to collection, and the like, the dispersion stability of abrasive grains contained in the polishing agent slurry is reduced such that the abrasive grains become agglomerated. Also, the change in pH of the recycled polishing agent slurry is the cause of the above problem. To address these issues, in the polishing agent recycling process for preparing the recycled polishing agent slurry finally, the pH value and electrical conductivity value of the recycled polishing agent slurry were adjusted to be in a certain range by adding a pH adjusting agent and a dispersing agent including components that interact with the component of the polished material mixed into the recycled polishing agent slurry, the ionic component dissolved from the components of the polished material, the metal ion component mixed during the processes from use as a polishing agent to collection, or the like. The inventors of the present application have found that this can reduce the decrease in polishing rate and the occurrence of scratches for each recycled polishing agent slurry, and have arrived at the present invention.

The above problems related to the present invention are solved by the following means.

To achieve at least one of the above-mentioned objects, a preparation method of a recycled polishing agent slurry from a used polishing agent slurry after polishing a material to be polished whose main component is silicon using a reference polishing agent slurry including a cerium oxide polishing agent and a dispersing agent reflecting one aspect of the present invention includes:

slurry collecting in which the used polishing agent slurry discharged from a polishing machine is collected;

separation and concentration in which the cerium oxide polishing agent in the used polishing agent slurry that has been collected is separated from a component derived from the material to be polished and then concentrated, and

polishing agent recycling in which a pH adjusting agent and the dispersing agent are added to the cerium oxide polishing agent that has been separated and concentrated, and a recycled polishing agent slurry is adjusted to have a pH value at 25° C. of in a range of 6.0 to 10.5 and an electrical conductivity value in a range of 0.10 to 10.00 times that of the reference polishing agent slurry.

To achieve at least one of the above-mentioned objects, a polishing agent slurry reflecting one aspect of the present invention includes:

an additive consisting of a dispersing agent and a pH adjusting agent;

a cerium oxide polishing agent; and

a glass component,

wherein the polishing agent slurry has a pH value at 25° C. in a range of 6.0 to 10.5, and

a mass ratio of the additive to the glass component is in a range of 0.8 to 5500.

### BRIEF DESCRIPTION OF THE DRAWINGS

The advantages and features provided by one or more embodiments of the invention will become more fully understood from the detailed description given hereinbelow and the appended drawings which are given by way of illustration only, and thus are no intended as a definition of the limits of the present invention, wherein:

FIG. 1 is a schematic diagram showing an example of a basic process flow of a preparation method of a recycled polishing agent slurry;

FIG. 2 is a summary diagram showing an example of a flow of a separation and concentration process (agglomeration precipitation method);

FIG. 3 is a summary diagram showing an example of a flow of a separation and concentration process (filter filtration method); and

FIG. 4 is a schematic diagram showing an example of a polishing agent recycling process using an ultrasonic dispersion machine.

### DETAILED DESCRIPTION OF THE EMBODIMENTS

The mechanism by which the effect of the invention is expressed and the mechanism by which the invention works is not clear, but is assumed to be as follows.

The following example is a case where, after a polishing process using an unused polishing agent slurry, the polishing agent slurry is recycled from the used polishing agent slurry. In this example, the polishing agent slurry to be recycled is supplied to the CMP device, used for the process, and then collected as a used slurry. In the recycling process, the polished material components contained in the used slurry are removed by various processes, and then dispersing agents and the like are added to produce a recycled polishing agent slurry. During the processes including use in the CMP process to the slurry collecting process, separation and concentration process, and the polishing agent recycling process, the unused polishing agent slurry is mixed with various components.

For example, the collected used polishing agent slurry is mixed with, in addition to the components of the polished material that exist in the slurry, ionic components dissolved from the components of the polished material, fragments of a polishing pad, and the like. When ultrapure water is used as the solvent to disperse the polishing agent slurry, carbonate ions, and the like, derived from carbon dioxide in the atmosphere is mixed in.

In the recycled polishing agent slurry, alkali metal ions (or alkaline earth metal ions), a dispersing agent, and the like are added to perform the recycling process. Among these, dissolved components from the polished material, carbonate ions mixed in from the atmosphere, alkali metal ions (or alkaline earth metal ions) added in the recycling process, components of the dispersing agent, and the like that are contained in the recycled polishing agent slurry affect the surface condition of the abrasive grains in the recycled polishing agent slurry, pH value of the recycled polishing agent slurry, and dispersing agent concentration, causing them to change in each recycling process. As a result, the dispersing stability of the cerium oxide polishing agent components contained in the recycled polishing agent slurry is reduced, and agglomeration of the abrasive grain component in the recycled polishing agent slurry occurs. Then, it was found that, each time the polishing agent slurry is recycled, the polishing rate is reduced, and scratches and “burn” (called “white burn” or “blue burn,” in which the surface of the polished material becomes cloudy white or colored due to an interference film) tends to occur.

Therefore, in the polishing agent recycling process to prepare the recycled polishing agent, the pH value of the recycled polishing agent slurry is kept in a certain range by adding a pH adjusting agent and a dispersing agent, and the value of the electrical conductivity of the recycled polishing agent slurry is kept in a certain range relative to the reference polishing agent slurry as an indicator of the concentration of the dispersing agent. As a result, the pH value and the concentration of the dispersing agent are maintained in the appropriate range. In this way, it is assumed that the reduction in polishing rate and the inconsistency in quality can be suppressed for each recycled polishing agent slurry.

In a preparation method of a recycled polishing agent slurry of the present invention, the recycled polishing agent slurry is prepared from a used polishing agent slurry after polishing a material to be polished whose main component is silicon, using a reference polishing agent slurry including a cerium oxide polishing agent and a dispersing agent. The preparation method includes: a slurry collection in which the used polishing agent slurry discharged from a polishing machine is collected; a separation and concentration in which the cerium oxide polishing agent in the used polishing agent slurry that has been collected is separated from a component derived from the material to be polished and concentrated, and recycling of polishing agent in which a pH adjusting agent and the dispersing agent are added to the cerium oxide polishing agent that has been separated and concentrated, thereby adjusting a recycled polishing agent slurry having a pH value at 25° C. in a range of 6.0 to 10.5 and an electrical conductivity value in a range of 0.10 to 10.00 times that of the reference polishing agent slurry.

These are technical features common to the following embodiments.

From the viewpoint of achieving the effects of the present invention, it is preferable that the reference polishing agent slurry is an unused polishing agent slurry.

From the viewpoint of achieving the effects of the present invention, it is preferable that the dispersing agent includes at least one of a water-soluble anionic dispersing agent, a water-soluble cationic dispersing agent, and a water-soluble amphoteric dispersing agent.

From the viewpoint of being able to collect recycled polishing agent slurry with a high cerium concentration, it is preferable that, in the separation and concentration, the cerium oxide polishing agent is separated from the component derived from the material to be polished and concentrated by filtration using a filter.

In the present invention, when separating cerium oxide polishing agent particles from components of polished material by adding an inorganic salt in the separation and concentration, a divalent alkaline earth metal salt as an inorganic salt is added to the polishing agent slurry that has been collected at a pH value at 25° C. in a range of 6.5 or more and less than 10.0, such that the cerium oxide polishing agent is separated from the component derived from the material to be polished and is concentrated. This allows effective separation of the cerium oxide polishing agent particles and polished material components contained in the collected used polishing agent slurry.

From the viewpoint of separating the cerium oxide polishing agent particles and the polished material components contained in the collected used polishing agent slurry, it is preferable that the divalent alkaline earth metal salt is a magnesium salt.

From the viewpoint of reducing contamination of unnecessary extra metal ions in the polishing process, it is preferable that the pH adjusting agent includes at least one of an inorganic acid, a carboxylic acid, an amine salt, and ammonium hydroxide.

The polishing agent slurry of the present invention includes an additive consisting of a dispersing agent and a pH adjusting agent, a cerium oxide polishing agent, and a glass component, and has a pH value at 25° C. in a range of 6.0 to 10.5, wherein a mass ratio of the additive to the glass component is in a range of 0.8 to 5500.

Hereinafter, one or more embodiments of the present invention will be described with reference to the drawings. However, the scope of the invention is not limited to the illustrated examples. In this specification, “to” means that the values before and after it are included as the lower and upper limits.

In the present invention, the “reference polishing agent slurry” is a polishing agent slurry that is used as a reference in the preparation of a recycled polishing agent slurry, and is a polishing agent slurry that is newly prepared depending on the purpose and application of the polishing agent slurry processing. In preparing a recycled polishing agent slurry from a used polishing agent slurry after a polishing process using the reference polishing agent slurry, the electrical conductivity value is adjusted in reference to the reference polishing agent slurry.

The reference polishing agent slurry is preferably an unused polishing agent slurry, but may be a recycled polishing agent slurry. In other words, the recycled polishing agent slurry may be newly prepared as the reference polishing agent slurry depending on the intended use.

### Preparation Method of Recycled Polishing Agent Slurry

The preparation method of recycled polishing agent slurry of the present invention is characterized in that, after polishing a material to be polished whose main component is silicon using a reference polishing agent slurry including a cerium oxide polishing agent and a dispersing agent, the preparation method includes: collecting a slurry in which the used polishing agent slurry discharged from a polishing machine is collected; separation and concentration in which the cerium oxide polishing agent in the used polishing agent slurry that has been collected is separated from a component derived from the material to be polished and then concentrated; and recycling of polishing agent in which a pH adjusting agent and the dispersing agent are added to the cerium oxide polishing agent that has been separated and concentrated, thereby adjusting a recycled polishing agent slurry having a pH value at 25° C. in a range of 6.0 to 10.5 and an electrical conductivity value in a range of 0.10 to 10.00 times that of the reference polishing agent slurry.

In this way, the pH adjusting agent and the dispersing agent that are added in the polishing agent recycling process interact with the components of the polished material mixed in the recycled polishing agent slurry, the ionic components derived from dissolved components of the polished material, the metal ion components mixed during the processes from use as a polishing agent to collection, or the like. As a result, the pH value of the recycled polishing agent slurry and the concentration of the dispersing agent are set in a certain range based on an electrical conductivity value as an indicator, thus the goal of the present invention can be achieved.

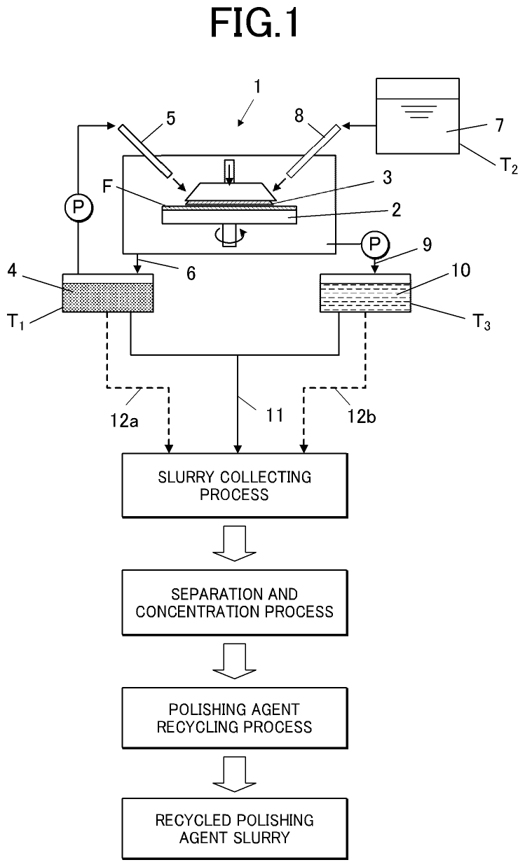

Now, the process flow of the preparation method of the recycled polishing agent slurry according to the present embodiment will be described. FIG. 1 is a schematic diagram showing an example of a basic process flow of preparing the recycled polishing agent slurry in the present embodiment.

In the polishing process illustrated in FIG. 1, a polishing device 1 has a rotatable polishing surface plate 2 to which a polishing cloth F made of non-woven fabric, synthetic resin foam, synthetic leather, or the like is attached. During polishing operation, the polishing surface plate 2 rotates while the material to be polished (for example, glass) 3 is pressed against the polishing surface plate 2 with a predetermined pressing force. At the same time, a polishing agent liquid 4 containing cerium oxide is supplied from the slurry nozzle 5 via a pump. The polishing agent liquid 4 containing cerium oxide is stored in a slurry tank T₁ through a flow path 6, and is repeatedly circulated through the polishing device 1 and the slurry tank T₁.

Washing water 7 for washing the polishing device 1 is stored in a washing water storage tank T₂, and is sprayed from the washing water jet nozzle 8 onto the polishing portion for washing. The washing liquid 10 containing the polishing agent is stored in the washing liquid storage tank T₃ via a pump and through a flow path 9. This washing liquid storage tank T₃ is used to store the washing water after being used for washing (rinsing). In order to prevent precipitation and agglomeration, the washing liquid is constantly stirred by a stirrer blade.

Both the polishing agent liquid 4 that is circulated and used during the polishing process and stored in the slurry tank T₁(polishing agent slurry 2, to be described later) and the washing liquid 10 that is stored in the washing liquid storage tank T₃ and includes the polishing agent (polishing agent slurry 1, to be described later) include non-polishing agents that are shavings of the polished material (for example, glass) 3 that has been polished in the polishing process 1, as well as cerium oxide particles as the polishing agent.

Next, the polishing agent liquid 4 and the washing liquid 10 including the polishing agent are collected, either as a mixed liquid of the two or as separate liquids. This process is referred to as a slurry collecting process.

Next, in the mixed liquid or separate liquids (hereinafter referred to as the mother liquid(s)) of the polishing agent liquid 4 and the washing liquid 10 including the polishing agent that are collected in the slurry collecting process, only the polishing agent is separated from the mother liquid without agglomerating the polished material (for example, glass components) and then concentrated (separation and concentration process).

In a preferred method of separating and concentrating the cerium oxide polishing agent from the component derived from the polished material, a divalent alkaline earth metal salt is added as an agglomerating agent to the collected mother liquid (hereinafter also referred to as an “agglomeration precipitation method”), or a filter is used (hereinafter also referred to as a “filter filtration method”). These methods can also be used in combination.

In the agglomeration precipitation method, a solid-liquid separation is preferably performed using natural sedimentation as the separation operation, without applying any forced separation method. After the mother liquid is separated into a supernatant liquid containing the polished material etc., and a concentrated liquid containing cerium oxide is precipitated in the lower part, the polishing agent is collected by a decantation method, for example, by draining the supernatant liquid by tilting the container, or by inserting a drain pipe into the container until it reaches near the interface between the supernatant liquid and the concentrated liquid and then draining only the supernatant liquid out of the container.

In the filter filtration method, it is preferable to dissolve the components of the non-polishing agent in advance, using water or other solvents as necessary, in order to obtain only the polishing agent as a residue by filtration.

Then, the pH adjusting agent and the dispersing agent are added to the separated and concentrated cerium oxide polishing agent. The pH adjusting agent interacts with the components of the polished material mixed into the recycled polishing agent slurry, the ionic components dissolving from the components of the polished material, or the metal ion components mixed in during the processes from use as a polishing agent to collection. As a result, the prepared recycled polishing agent slurry has a pH value at 25° C. in the range of 6.0 to 10.5 and an electrical conductivity value in the range of 0.10 to 10.00 times that of the reference polishing agent slurry (polishing agent recycling process).

By adding the pH adjusting agent and the dispersing agent in this way, the pH value of the recycled polishing agent slurry and the electrical conductivity value of the recycled polishing agent slurry as an indicator of the concentration of the dispersing agent can be adjusted to be in a certain range relative to those of the reference polishing agent slurry. This is assumed to suppress the reduction in the polishing rate and the inconsistency in quality.

When cerium oxide particles have formed agglomerates (secondary particles) in the concentrate containing the concentrated cerium oxide, it is preferable to control the particle diameter by dispersing the cerium oxide particles to a desired particle diameter using a dispersing device after adding the dispersing agent and the pH adjusting agent in the polishing agent recycling process, such that the cerium oxide particles are loosened to form almost independent primary particles.

In this way, a high quality recycled polishing agent slurry can be obtained by a simple method.

Next, details of the preparation method of the recycled polishing agent slurry and the constituent technologies will be described.

### Polishing Agent

Generally used polishing agents for optical glass, semiconductor substrate, or the like include fine particles of bengara (αFe₂O₃), cerium oxide, aluminum oxide, manganese oxide, zirconium oxide, colloidal silica, or the like, dispersed in water or oil and made into a slurry. In the present invention, a polishing agent with cerium oxide as its main component is used, which is applicable to the chemical mechanical polishing (CMP) process. In the CMP process, polishing is carried out both physically and chemically. This provides sufficient processing rate while maintaining highly accurate flatness in the polishing process of a semiconductor substrate surface, glass, and the like.

Cerium oxide used as the polishing agent may be high-purity cerium oxide, which has almost 100% of cerium oxide content, and may not be a pure cerium oxide manufactured by calcination of bastnaesite, that is an ore containing rare earth elements other than cerium, and then by grinding it. Rare earth elements such as lanthanum, neodymium, and praseodymium are included as rare earth components, and besides oxides, fluorides and the like may also be included.

In the present invention, cerium oxide polishing agents that are generally available on the market can be used regardless of their composition and shape. In particular, polishing agents with a cerium oxide content of 50 mass % or more are highly effective and preferred.

### Polishing Process

The polishing agent is used in the following manner (polishing process).

The material to be polished may be a silicon-based material, such as optical glass, a glass substrate for information storage medium, cover glass for smartphones, an in-vehicle display, and a silicon wafer. A polishing process of a glass substrate usually includes a series of steps, for example, preparation of the polishing agent slurry, polishing process, and washing, as illustrated in FIG. 1.

### (1) Preparation of Reference Polishing Agent Slurry

The reference polishing agent slurry is a polishing agent slurry that is used as a reference in the preparation of the recycled polishing agent slurry, and is a polishing agent slurry that is newly prepared depending on the purpose and application of the polishing agent slurry processing.

When the reference polishing agent slurry is an unused polishing agent slurry, the polishing agent slurry is preferably prepared so that the content of the polishing agent is 0.1 to 40% by mass in a solvent such as water using a dispersing agent and a powder of polishing agent with cerium oxide as the main component. Cerium oxide fine particles used as the polishing agent have an average particle diameter (particle size (D50)) of several tens of nm to several micrometers.

In the present invention, agglomeration of cerium oxide particles is prevented by adding the dispersing agent. Furthermore, by constantly stirring using a stirrer or the like, the cerium oxide particles are prevented from sedimentation and maintain their dispersion state. In a generally and preferably adopted method, a tank for the polishing agent slurry is placed next to a polishing device, the dispersion state is maintained by using a stirrer, etc., and a supply pump is used for circulating supply to the polishing device.

The reference polishing agent slurry is preferably an unused polishing agent slurry, but it may also be a recycled polishing agent slurry. That is, the recycled polishing agent slurry can be newly prepared as the reference polishing agent slurry depending on the purpose and application.

For example, a used polishing agent slurry that has been used in the polishing process of quartz glass can be collected to prepare a recycled polishing agent slurry in accordance with the present invention, which can in turn be used as a new reference polishing agent slurry for polishing aluminosilicate glass by adding a different additive and the like appropriate for the reference polishing agent slurry for polishing aluminosilicate glass. Such a recycled polishing agent slurry can be used as a reference polishing agent slurry to further prepare a recycled polishing agent slurry for polishing aluminosilicate glass in accordance with the present invention.

A new slurry is prepared as the reference polishing agent slurry in this way when the material to be polished is different as described above, or when the polishing process of a single product involves multiple polishing processes such as a rough polishing process and a precision polishing process. Additives to be added to the newly prepared reference polishing agent slurry include a pH adjusting agent or a dispersing agent.

### Dispersing Agent

Examples of the dispersing agent include a water-soluble anionic dispersing agent, a water-soluble cationic dispersing agent, and a water-soluble amphoteric dispersing agent. Examples of the preferred dispersing agent also include ammonium polyacrylate, a copolymer of acrylamide and ammonium acrylate, and a maleic acid polyacrylate copolymer.

Two or more dispersing agents may be used together, including at least one polymeric dispersing agent containing ammonium acrylate salt as a copolymer component and at least one selected from among a water-soluble anionic dispersing agent, a water-soluble cationic dispersing agent, and a water-soluble amphoteric dispersing agent.

Among these, examples of the dispersing agent preferably used in the present invention include a water-soluble anionic dispersing agent, a water-soluble cationic dispersing agent, and a water-soluble amphoteric dispersing agent, from the viewpoint of measuring and controlling the amount of the dispersing agent in the recycled polishing agent slurry based on an electrical conductivity value as an indicator.

For use in polishing in the manufacture of semiconductor devices, the content of metal elements such as sodium ions and potassium ions in the dispersing agent is preferably at 10 ppm or less.

### Water-Soluble Anionic Dispersing Agent

Examples of anionic dispersing agent include triethanolamine lauryl sulfate, ammonium lauryl sulfate, triethanolamine polyoxyethylene alkyl ether sulfate, a polycarboxylic acid type polymer dispersing agent, and the like.

Examples of the polycarboxylic acid type polymer dispersing agent include a polymer of a carboxylic acid monomer having an unsaturated double bond such as acrylic acid, methacrylic acid, maleic acid, fumaric acid, or itaconic acid, a copolymer of a carboxylic acid monomer having an unsaturated double bond and another monomer having an unsaturated double bond, and their ammonium salts, amine salts, and the like.

### Water-Soluble Cationic Dispersing Agent

Examples of the cationic dispersing agent include primary to tertiary aliphatic amines, quaternary ammonium, tetraalkylammonium, trialkylbenzylammonium alkylpyridinium, 2-alkyl-1-alkyl-1-hydroxyethylimidazolinium, N,N-dialkylmorpholinium, polyethylene polyamine fatty acid amides, urea condensates of polyethylene polyamine fatty acid amides, quaternary ammonium of urea condensates of polyethylene polyamine fatty acid amides, and salts thereof.

### Water-Soluble Amphoteric Dispersing Agent

Betaine dispersing agents are preferred as the water-soluble amphoteric dispersing agents. The Betaine dispersing agents include, for example, betaines such as N,N-dimethyl-N-alkyl-N-carboxymethylammonium betaine, N,N,N-trialkyl-N-sulfoalkyl ammonium betaine, N,N-dialkyl-N,N-bis-polyoxyethylene ammonium sulfate betaine, 2-alkyl-1-carboxymethyl-1-hydroxyethylimidazolinium betaine; and aminocarboxylic acids such as N,N-dialkylaminoalkylene carboxylates.

### Addition Amount of Dispersing Agent

Addition amount of the dispersing agent is preferably in the range of 0.01 to 5.0 parts by mass with respect to 100 parts by mass of cerium oxide particles based on the relationship between the dispersing ability and prevention of sedimentation of the polishing agent particles in the polishing agent slurry, polishing scratches, and the addition amount of the dispersing agent. The molecular weight of the dispersing agent is preferably in the range of 100 to 50000, and more preferably in the range of 1000 to 10000. When the molecular weight of the dispersing agent is 100 or more, enough polishing rate can be achieved. When the molecular weight of the dispersing agent is 50000 or less, the increase in viscosity can be suppressed and the storage stability of the CMP polishing agent can be ensured.

As a method of dispersing these polishing agent particles in water, a homogenizer, ultrasonic dispersing machine, wet ball mill, or the like can be used as well as the usual dispersion process using a stirrer. The particle diameter (D50) of the polishing agent particles in the polishing agent slurry prepared in this way is preferably in the range of 0.01 to 1.0 μm. When the particle diameter (D50) of the polishing agent particles is 0.01 μm or more, a high polishing rate can be achieved. When the particle diameter (D50) of the polishing agent particles is 1.0 μm or less, scratches on the surface of the material to be polished can be prevented during the polishing process.

### (2) Polishing

As shown in FIG. 1, a polishing pad (polishing cloth) is brought into contact with a glass substrate, for example, as the material to be polished. Then, while the polishing agent slurry is supplied to the contacting surface, the polishing pad and the glass substrate are moved relative to each other under pressurized conditions to polish the glass substrate.

### (3) Washing

Immediately after the polishing, a large amount of polishing agent adheres to the glass substrate and the polishing device. Therefore, as illustrated in FIG. 1, water and the like is supplied instead of the polishing agent slurry after polishing in order to wash the polishing agent adhered to the glass substrate and polishing device. At this time, the washing liquid containing the polishing agent is drained out of the system.

Since a certain amount of polishing agent is drained out of the system during this washing operation, the amount of polishing agent in the system is decreased. To compensate for this decrease, a new polishing agent slurry can be added to the slurry tank T₁. The addition can be done for each time of the processing or for every certain amount of processing, but in any case, it is desirable to supply the polishing agent that is well dispersed in the solvent.

### Used Polishing Agent Slurry

The used polishing agent slurry in the present invention is a polishing agent slurry that is drained outside the system consisting of the polishing device and the tank for the polishing agent slurry, and is mainly of two types as shown below.

The first one is the polishing agent slurry 1 (rinse slurry) that contains the washing liquid drained during the washing process, and the second one is the used polishing agent slurry 2 (life end) stored in the slurry tank T₁ that is discarded after a certain number of times of use. In the present invention, they are referred to as the polishing agent slurry 1 and the polishing agent slurry 2. The present invention is preferably applied to both of the polishing agent slurrys 1 and 2, but may be applied to only one of them.

The polishing agent slurry 1 that includes washing water is characterized by the following two points.

(1) Since the polishing agent slurry 1 is drained during washing with a large amount of washing water, the concentration of the polishing agent is lower than that of the slurry in the tank.
(2) Glass components adhering to the polishing cloth and the like also flow into this polishing agent slurry 1 during washing.

On the other hand, the used polishing agent slurry 2 is characterized by a higher concentration of the polished material component compared to the polishing agent slurry before use.

### Preparation of Recycled Polishing Agent Slurry

As outlined in FIG. 1, the preparation method of recycled polishing agent slurry generally includes three processes: slurry collecting process, separation and concentration process, and polishing agent recycling process.

### 1: Slurry Collecting Process

In this process, the polishing agent slurry drained out of the system including the polishing machine and the tank for slurry is collected. The polishing agent slurry to be collected includes two types of slurry, namely, the polishing agent slurry 1 containing the above-mentioned washing water and the used polishing agent slurry 2.

Generally, the collected polishing agent slurry includes cerium oxide polishing agent in the range of 0.01 to 40% by mass.

The collected polishing agent slurry may proceed to the separation process immediately after collection, or may be stored until a certain amount of the slurry is collected. In either case, the collected slurry is preferably stirred continuously to maintain its dispersion state.

In the present invention, the polishing agent slurry 1 and the polishing agent slurry 2 collected in the slurry collecting process may be mixed to prepare a mother liquid, and then processed in the subsequent separation and concentration process. Alternatively, the polishing agent slurry 1 and the polishing agent slurry 2 collected in the slurry collecting process may be separately processed in the subsequent separation and concentration process as independent mother liquids.

### 2: Separation and Concentration Process

As mentioned above, the separation and concentration process can be done using the agglomeration precipitation method or the filter filtration method.

### Agglomeration Precipitation Method

In the agglomeration precipitation method, a divalent alkaline earth metal salt or a monovalent alkaline metal salt as an inorganic salt is added to the polishing agent slurry (mother liquid) collected in the slurry collecting process, and the cerium oxide polishing agent is separated from the component derived from the polished material and is concentrated.

Specifically, a divalent alkaline earth metal salt as an inorganic salt is preferably added to the collected polishing agent slurry (mother liquid) at a pH value at 25° C. in the range of 6.5 or more and less than 10.0, and the cerium oxide polishing agent is preferably separated from the component derived from the polished material and concentrated. By doing so, only the polishing agent component, which is mainly cerium oxide, is agglomerated and precipitated, and then the agglomerate is separated from the glass component, which is mostly present in the supernatant. This makes it possible to separate the cerium oxide component from the glass component and to concentrate the polishing agent slurry at the same time. The alkaline earth metal salt is used as the agglomerating agent to selectively agglomerate and precipitate the cerium oxide contained in the used polishing agent slurry.

The pH adjusting agent used for adjusting the pH value may be the same as the pH adjusting agent described in the polishing agent recycling process described later.

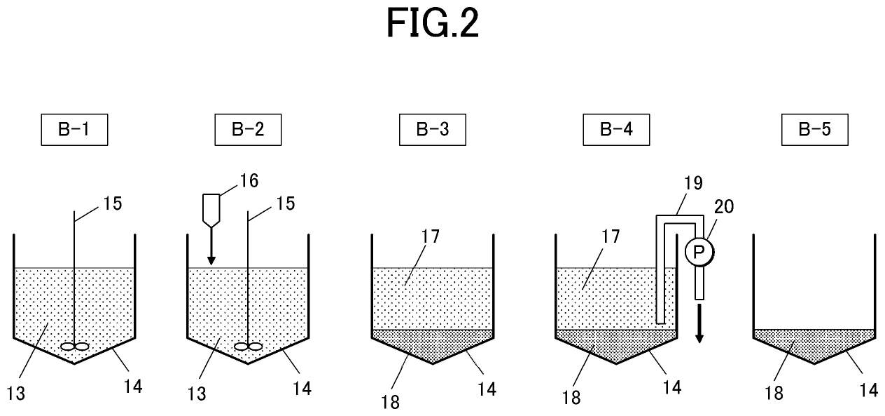

The specific operations are described using FIG. 2.

FIG. 2 is a schematic diagram showing an example of the flow of the separation and concentration process (agglomeration precipitation method) in the preparation method of the recycled polishing agent slurry.

In Step (B-1), the polishing agent slurry (mother liquid) 13 that has been collected in the previous slurry collecting process is fed into an adjusting kettle 14 having a stirrer. Then, in Step (B-2), while the polishing agent slurry (mother liquid) 13 is being stirred, its pH value at 25° C. is adjusted to be 6.5 or more and less than 10.0. After that, the divalent alkaline earth metal salt as an inorganic salt is added to the polishing agent slurry (mother liquid) 13 from an additive container 16. Next, in Step (B-3), due to the addition of the inorganic salt, only the cerium oxide particles contained in the polishing agent slurry (mother liquid) 13 are agglomerated and sediment to the bottom to form agglomerate 18. A supernatant liquid 17 after separation and sedimentation of cerium oxide includes a non-polishing component such as glass, and the polishing agent and the non-polishing component are separated from each other.

### Divalent Alkaline Earth Metal Salt

In the present invention, the inorganic salt used for agglomeration of cerium oxide is preferably a divalent alkaline earth metal salt.

The divalent alkaline earth metal salts related to the present invention include, for example, calcium salts, barium salts, beryllium salts, magnesium salts, and the like. Among them, from the viewpoint of being able to better express the effects of the present invention, the divalent alkaline earth metal salt is preferably a magnesium salt.

Magnesium salts applicable to the present invention are not limited as long as they function as electrolytes, but magnesium chloride, magnesium bromide, magnesium iodide, magnesium sulfate, and magnesium acetate are preferred because of their high solubility in water. Magnesium chloride and magnesium sulfate are particularly preferred because of the small pH change of the solution and the easy treatment of sediment of the polishing agent and waste solution.

### Addition Method of Divalent Alkaline Earth Metal Salt

In the following, a method of adding magnesium salts, which are divalent alkaline earth metal salts, is described.

### (a) Concentration of Magnesium Salt

The magnesium salt to be added may be supplied as a powder directly to the collected slurry or dissolved in a solvent such as water before being added to the polishing agent slurry. In either case, the magnesium salt is preferably added to the polishing agent slurry in a state dissolved in a solvent so as to be uniform in the slurry.

Preferably, the concentration of the aqueous solution is 0.5 to 50% by mass. In order to reduce pH variation in the system and to improve the efficiency of separation from the glass component, it is more preferably from 1 to 10% by mass.

### (b) Temperature during Addition of Magnesium Salt

The temperature at which the magnesium salt is added can be appropriately selected from above the temperature at which the collected polishing agent slurry freezes and 90° C. However, from the viewpoint of effective separation from the glass component, the temperature is preferably in the range of 10 to 40° C., and more preferably in the range of 15 to 35° C.

### (c) Addition Rate of Magnesium Salt

The magnesium salt is preferably added at a rate that ensures that the magnesium concentration in the collected polishing agent slurry does not become locally high but is uniform. The amount of magnesium salt added per minute is preferably 20% or less of the total amount to be added, and more preferably 10% or less of the total amount to be added.

### (d) pH Value during Addition of Magnesium Salt

In the separation and concentration process, separation and concentration are preferably performed by adding the magnesium salt, at a pH value of the mother liquid at 25° C. of 6.5 or more and less than 10.0.

### (e) Stirring after Magnesium Salt Addition

After adding the magnesium salt, it is preferable to continue stirring for at least 10 minutes, and more preferably for at least 30 minutes. Although agglomeration of polishing agent particles starts as soon as the magnesium salt is added, continuing stirring makes the agglomeration state uniform throughout the system and the particle size distribution of the agglomerates narrower, thereby allowing for easy separation afterwards.

As shown in FIG. 2, after separating the supernatant liquid 17 containing glass components and the agglomerate 18 containing cerium oxide particles, the agglomerate 18 is collected.

### (f) Separation Method of Agglomerate of Polishing Agent

Any conventional separation method of agglomerate can be used to separate the agglomerate of polishing agent agglomerated due to addition of the magnesium salt and the supernatant liquid. That is, natural sedimentation can be used to separate only the supernatant, or a physical method such as centrifugation can be used. From the viewpoint of purity of recycled cerium oxide-containing polishing agent, natural sedimentation is preferred.

The slurry from which the supernatant liquid has been separated has a higher specific gravity and is more concentrated than the collected slurry. This slurry contains cerium oxide in a concentration higher than that of the collected slurry.

An example of a method for separating the agglomerates (agglomerated polishing agent) from the supernatant liquid is as follows. As shown in Step (B-3) of FIG. 2, the supernatant liquid 17 including the non-polishing agent and the like, and the agglomerate 18 that is the concentrate containing cerium oxide precipitated at the bottom are separated by natural sedimentation. Then, in Step (B-4), a drain pipe 19 is inserted into the kettle 14 until it reaches near the interface between the supernatant liquid and the agglomerate 18 and then draining only the supernatant liquid out of the kettle using a pump 20. Then, in Step (B-5), the agglomerate 18 containing the polishing agent is collected.

### Filter Filtration Method

The filter filtration method is a method of separating and concentrating the cerium oxide polishing agent from the components derived from the polished material by filter filtration. When the recycled polishing agent slurry obtained by separating and concentrating the polishing agent by the agglomeration precipitation method is used for polishing, metallic elements may be contaminated in the polished material.

In the technical field of semiconductors, for example, in the polishing of silicon oxide layer, it is preferable to use the filter filtration method for the separation and concentration process to avoid contamination of metallic elements.

In the filter filtration method, the components of the non-polishing agent is preferably dissolved in advance using water or other solvents as necessary so as not to be agglomerated, in order to obtain only the polishing agent as a residue. Foreign matter, such as fragments of polishing pads, may be removed as needed.

### Foreign Matter Removal

The polishing agent slurry (mother liquid) collected in the slurry collecting process sometimes contains foreign matter from polishing pads etc. other than the washing water and used polishing agent slurry. The foreign matter is preferably removed using a filter of pore diameter 20 to 100 μm.

### Dissolution

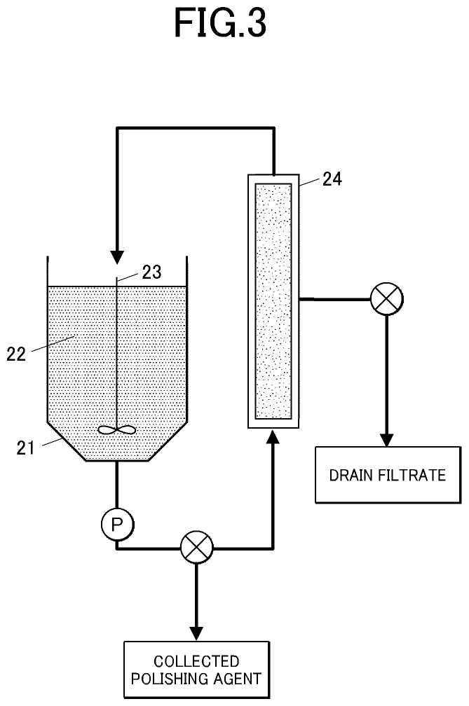

The collected polishing agent slurry 22, from which foreign matter has been removed by the foreign matter removal process, is fed into a tank 21 in a filter filtration device with a temperature controller (see FIG. 3).

Here, in order to check the concentration of polished material components, for example, silica, in the collected slurry, it is also preferable to perform a component analysis using ICP optical emission spectrometry plasma. The content of the polished material component can be determined by the component analysis. As a result, it is possible to adjust the amount of solvent to be added and the number of times the dissolution and filtration processes are repeated.

A solvent is then added to the collected slurry in which the concentration of the polished material component is known, and the polished material is dissolved by stirring using a stirrer 23.

The amount of solvent added is preferably adjusted depending on the concentration of the polished material component in the polishing agent slurry. In particular, the solvent is preferably added to the polishing agent slurry such that the concentration of the polished material is adjusted to be 1.8 times or less of its saturation solubility. When the concentration of the polished material is 1.8 times or less of its saturation solubility, the collected polishing agent can be easily reused.

It is also preferable to heat the collected slurry in the tank, particularly to a temperature in the range of 40 to 90° C.

By adding solvent and heating as needed, the polished material component is further dissolved, while the polishing agent component is not dissolved in the solvent, and thus they can be separated using a filter.

Water is the preferred solvent to be added, but other solvents that do not contain metal ions, such as acetone, ethanol, methanol, ethylene glycol, propylene glycol, and the like may be added in small quantities.

### Filtration

The polishing agent slurry, in which the polished material components are dissolved, is filtered using a filtration filter 24. Through the filtration, the filtrate in which the polished material component is drained, and the dispersion in which the polishing agent is dispersed is collected.

The filtration filters used in filtration are not particularly limited and include, for example, hollow fiber filters, metal filters, thread-wound filters, ceramic filters, roll-type polypropylene filters, and the like.

Preferably applied ceramic filters include, for example, ceramic filters manufactured by TAMI Industries in France, Ceramic filters manufactured by Noritake. Co., Ltd., Japan, ceramic filters manufactured by NGK insulators, Ltd. (for example, SERA LEC DPF, Cefilt, and the like), ceramic filters manufactured by Pall Corporation.

It is also preferable to perform filtration before dissolution to separate the filtrate, followed by dissolution. This allows for efficient removal of the polished material component.

### Continual Dissolution

It is also preferable to perform dissolution and filtration repeatedly, that is, to perform continual dissolution. In the continual dissolution, the dissolution and filtration may be repeated after removal of foreign matter and filtration.

The solvent is preferably added to the polishing agent slurry such that the concentration of the polished material is adjusted to be 1.8 times or less of its saturation solubility.

Specifically, the amount of the added solvent is preferably adjusted such that the concentration is 1.8 times or less of solubility of silica at the temperature, more preferably, the amount of the added solvent is preferably adjusted such that the concentration is the solubility or less. The amount of the solvent is also preferably adjusted by heating.

Here, 1.8 times or less of the saturation solubility of the polished material means that the polished material component dissolved and dispersed in the solvent is 1.8 times or less of the saturation solubility of the polished material at the temperature. When the concentration is 1.8 times or less of the saturation solubility, the agglomeration of the polished material components dispersed in the solvent can easily become dispersed, and the efficiency of separation and purification is improved.

### Concentration

After the filtration, including the continual dissolution process, concentration is performed to achieve a desired concentration of the polishing agent in the range of 0.1 to 40% by mass.

When the concentration of polishing agent is 0.1% by mass or more, it is possible to obtain a polishing agent having a high polishing performance. When the concentration of polishing agent is 40% by mass or less, it is possible to obtain a polishing agent slurry having an appropriate concentration that does not clog the filter.

### 3: Polishing Agent Recycling Process

In the polishing agent recycling process, the recycled polishing agent slurry is prepared as follows. To the cerium oxide polishing agent concentrated in the separation and concentration process, the polished material component mixed in the recycled polishing agent slurry, a pH adjusting agent that interacts with ionic components dissolving from the polished material component or metal ions mixed during the processes from use as a polishing agent to collection, and a dispersing agent are added, such that the pH value at 25° C. is in the range of 6.0 to 10.5 and that the electrical conductivity value is in the range of 0.10 to 10.00 times that of the reference polishing agent slurry.

By adding the pH adjusting agent and dispersing agent in this way, the pH value of the recycled polishing agent slurry and the electrical conductivity value of the recycled polishing agent slurry as an indicator of the concentration of the dispersing agent can be adjusted to be in a certain range relative to the reference polishing agent slurry. This can suppress the reduction in polishing rate and the inconsistency in quality.

It is also possible to prepare a recycled polishing agent slurry from the reference polishing agent slurry, and after polishing process using the recycled polishing agent slurry, the recycled polishing agent slurry can be further prepared according to the present invention from the collected polishing agent slurry. Although it is possible to recycle the polishing agent slurry multiple times in this manner, the electrical conductivity of each recycled polishing agent slurry is adjusted with respect to the reference polishing agent slurry.

### Adjustment of Electrical Conductivity Value and pH Value

Next, the amount of the dispersing agent to be filled in the concentrated polishing agent slurry prepared in the above process is determined. In the present invention, the fill amount of the dispersing agent is adjusted such that the electrical conductivity value of the recycled polishing agent slurry is 0.10 to 10.00 times with respect to that of the reference polishing agent slurry, and such that the pH value at 25° C. equivalent is in the range of 6.0 to 10.5. More preferably, the pH value is adjusted to be in the range of 7.0 to 10.0, and even more preferably, it is adjusted to be in the range of 8.0 to 9.5.

The dispersing agent to be added is preferably the same as that used in the polishing process. When the content of the dispersing agent is increased, the electrical conductivity increases proportionally. Therefore, the amount of the dispersing agent in the polishing agent slurry can be easily grasped by measuring the electrical conductivity.

The amount of the dispersing agent to be added is adjusted by adjusting the electrical conductivity to be in the above range with respect to the electrical conductivity of the reference polishing agent slurry.

For example, when the reference polishing agent slurry is a recycled polishing agent slurry, it may contain metal ions or other substances that affect electrical conductivity. Therefore, the amount of the dispersing agent to be added needs to be adjusted more than when the reference polishing agent slurry is an unused polishing agent slurry.

The electrical conductivity can be determined by measuring from a sample liquid warmed to 25° C. by using, for example, Electrical conductivity meter ES-51 (manufactured by HORIBA, Ltd.), Electrical conductivity meter CM-30G (manufactured by DKK-TOA CORPORATION), Lakom tester handheld electrical conductivity meter CyberScan CON 110 (manufactured by asOne CO,.LTD.), Compact electrical conductivity meter LAQUAtwin B-771 (manufactured by HORIBA, Ltd.), and the like.

### pH Adjusting Agent

Acids or alkalis added as the pH adjusting agent are not particularly limited, and can be inorganic acids, organic acids, or the like. However, when polishing materials such as silicon oxide layers that are used in the semiconductor field, it is preferable to use a pH adjusting agent that does not contain metallic elements.

The pH adjusting agent is preferably an inorganic acid, carboxylic acid, amine base, or ammonium hydroxide.

The pH value used here is the value measured at 25° C. using a Lakom tester tabletop-type pH meter (pH 1500 manufactured by asOne Co,.Ltd.)

### Particle Diameter Control

In the polishing agent recycling process, it is desirable to adjust the particle diameter distribution of cerium oxide particles.

In particular, when cerium oxide particles are collected by agglomerating them using a magnesium salt and the like, it is preferable to re-disperse the agglomerated particles in order to loosen them up. The agglomerated polishing agent component is re-dispersed to adjust the particle diameter distribution to be equivalent to that of the polishing agent slurry before processing.

The agglomerated polishing agent particles are re-dispersed by using a dispersing machine or the like, to crush the agglomerated polishing agent particles. The dispersing machine may be an ultrasonic dispersing machine, a medium agitating mill such as a sand mill or bead mill, and the like, and is particularly preferably an ultrasonic dispersing machine.

Ultrasonic dispersion machines are commercially available from, for example, SMT Corporation, Ginsen Corporation, TAITEC Corporation, Branson, Kinematica AG, and NIHONSEIKI KAISHA LTD. UDU-1 and UH-600MC (manufactured by SMT Corporation), GSD600CVP (manufactured by Ginsen Corporation), RUS600TCVP (manufactured by NIHONSEIKI KAISHA LTD.), or the like may be used. The frequency of ultrasonic waves is not particularly limited.

Examples of circulating type machines that perform mechanical stirring and ultrasonic dispersion simultaneously and in parallel include, but are not limited to, UDU-1 and UH-600MC (manufactured by SMT Corporation), GSD600RCVP and GSD1200RCVP (manufactured by Ginsen Corporation), RUS600TCVP (manufactured by NIHONSEIKI KAISHA LTD.).

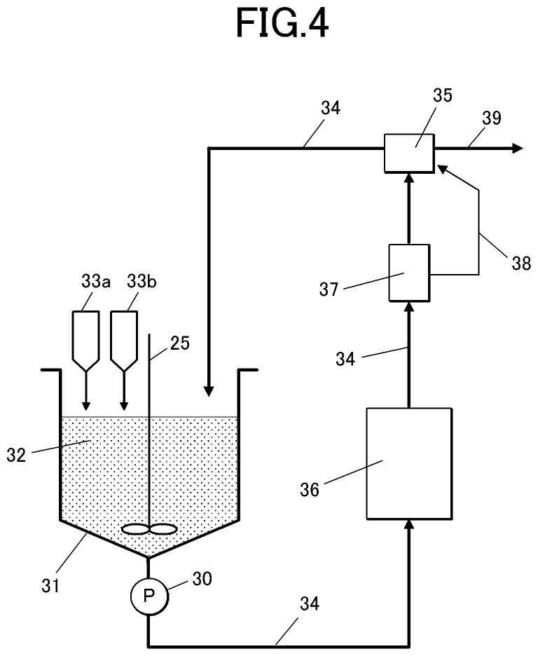

FIG. 4 is a schematic diagram showing an example of the polishing agent recycling process using the ultrasonic dispersion machine.

As shown in FIG. 4, water is added to the concentrated polishing agent, for example. After the cerium oxide dispersion liquid 32 is stored in the preparation kettle 31, the dispersing agent and the pH adjusting agent are added from the addition tanks 33a and 33b while stirring with the stirrer 25. After the electrical conductivity and pH values are adjusted to the desired values, the liquid is dispersed by an ultrasonic dispersion machine 36 through a flow path 34 via a pump 30 to loosen the agglomerated cerium oxide particles. Then, the particle diameter distribution of the cerium oxide particles after dispersion is monitored by a particle diameter measuring device 37 provided downstream. After the particle diameter distribution of the cerium oxide dispersion 32 has reached the desired conditions, a three-way valve 35 is operated and the cerium oxide dispersion 32 passes through the flow path 39 to be made into a recycled polishing agent slurry.

### Polishing Agent Slurry

The recycled polishing agent slurry prepared by the above described preparation method of recycled polishing agent slurry was found to have a certain relationship between the contained glass components and the additives as a polishing agent slurry.

That is, the polishing agent slurry of the present invention includes additives comprising a dispersing agent and a pH adjusting agent, cerium oxide polishing agent, and a glass component, and has a pH value at 25° C. in the range of 6.0 to 10.5, and the mass ratio of the additives to the glass component is in the range of 0.8 to 5500.

Although it is not clear why the above configuration can achieve the effect of the present invention, it is presumed as follows. When the polished material component (glass component) in the recycled slurry and the ionic component dissolving from the polished material component are adsorbed on the surface of the abrasive grains in the polishing agent slurry, the particle surface state changes, resulting in a decrease in dispersion stability of the abrasive grains in the slurry and causing agglomeration of the particles. As a result, a decrease in polishing rate and the occurrence of scratches are prevented.

Because the pH adjusting agent and dispersing agent described in the Examples are added to the polishing agent slurry containing polished material components or ionic components dissolving from the polished material based on the prescribed mass ratios, it is presumed that the additives interact with the polished material component or ionic component dissolving from the polished material component, preventing it from adsorbing on the surface of the abrasive grain component, thereby enhancing the dispersion stability of the abrasive grain component.

Regarding the ratio of the amount of additives to the glass component, for the reasons described above, it is believed that the effect is achieved by adding more than a certain amount of the additive with respect to the polished material.

When the mass ratio of the dispersing agent to the glass component is less than 0.8, it is difficult to obtain the expected effect. On the other hand, an excessive amount of additives (for example, a mass ratio of the dispersing agent to the glass component exceeding 5500) may cause a large change in the pH of the polishing agent slurry itself or adsorption of these additive components on the cerium oxide abrasive grains, which may adversely affect the polishing process. Therefore, the ratio needs to be in the above range. The mass ratio of the dispersing agent to the glass component is preferably in the range of 10.0 to 1000, more preferably in the range of 50.0 to 600.

### Measurement of Mass Ratio of Additives to Glass Component

The mass of the glass component can be analyzed by component analysis using ICP optical emission spectrometry plasma. The mass of the additive is obtained using the fed amount in the recycling process. These were used to calculate the above ratio.

### EXAMPLES

Hereinafter, the invention will be specifically described with reference to examples, but the invention is not limited to these examples. In the examples, “%” is used to indicate “% by mass” unless otherwise noted.

### Example 1

The following is an example of the preparation method of recycled polishing agent slurry using the agglomeration precipitation method in the separation and concentration process. Unless otherwise noted, the preparation of the polishing agent slurry was basically conducted under the conditions of 25° C. and 55% RH. At this time, the temperature of the solution and the like is also 25° C.

### Preparation of Reference Polishing Agent Slurry 1

Maleic acrylate copolymer was added to pure water as a dispersing agent, and the mixture was stirred with a stirrer for 5 minutes. After that, cerium oxide (E21, Mitsui Mining & Smelting Co., Ltd.) was added while stirring, and after stirring with a stirrer for 30 minutes, dispersion was carried out with an ultrasonic dispersing machine (manufactured by Branson).

Cerium oxide was added such that its concentration was 10% by mass, and the dispersing agent was added such that its ratio with respect to cerium oxide was 5% by mass. The polishing agent slurry was prepared so that the total volume was 50 liters.

After that, the pH and electrical conductivity values of the prepared reference slurry 1 were measured under the respective conditions described above. Subsequently, the pH value was adjusted to 8.5 using ammonia water as a pH adjusting agent. After that, the particle diameter (D50) was measured by the method described above.

The following measurement devices were used.

pH value: Lakom tester tabletop-type pH meter (pH 1500 manufactured by asOne Co,.Ltd.)

Electrical conductivity value: Compact electrical conductivity meter LAQUAtwin B-771 (manufactured by HORIBA, Ltd.)

The particle diameter (D50) was 0.96 μm.

### Preparation of Recycled Polishing Agent Slurry 1

A recycled polishing agent slurry 1 was prepared according to the following manufacturing process.

### Polishing Process

### Polishing

The polishing process of aluminosilicate glass substrates was carried out under the following conditions.

In the polishing process illustrated in FIG. 1, the unused reference polishing agent slurry 1 prepared as described above was used as the reference polishing agent slurry, and was supplied to a surface to be polished while the surface to be polished was polished with a polishing cloth. The polishing process was performed while the reference polishing agent slurry 1 was supplied in circulation at a flow rate of 5 L/min. The object to be polished was an aluminosilicate glass substrate with a diameter of 65 mm, and the polishing cloth was made of polyurethane. The pressure applied to the surface to be polished during polishing was set to 9.8 kPa (100 g/cm²), and the rotation rate of the polishing testing machine was set at 100 min⁻¹ (rpm), and the polishing process was performed for 30 minutes. The polishing process was performed for 10 batches each including 70 substrates, that is, for a total of 700 pieces.

Aluminosilicate glass substrate contained 60% by mass of silicon oxide, 15% by mass of oxides of an alkali metal and an alkaline earth metal, and 25% by mass of aluminum oxide and other components.

### Slurry Collecting Process

After polishing was completed, the drained wash water including the polishing agent slurry and the polishing agent slurry including the used polishing agent were collected to obtain 1000 liters of collected slurry liquid.

### Separation and Concentration Process

The collected slurry liquid was first filtered using a cartridge filter with a pore diameter of 25 μm, and then filtered using a cartridge filter with a pore diameter of 10 μm to remove foreign matter.

Next, while the collected slurry liquid was stirred to prevent the cerium oxide from sedimenting, 2.5 liters of a 1.0% by mass of magnesium chloride solution was added to the slurry solution over a period of 10 minutes. The pH value at 25° C. was 7.80 immediately after the magnesium chloride was added.

After 30 minutes of continuous stirring under the above conditions, the mixture was left still for 1.5 hours, and the supernatant liquid and the agglomerate were separated by sedimentation using the natural sedimentation method. After 1.5 hours, according to Step (B-4) in FIG. 2, the supernatant liquid was drained using a drain pump, and the agglomerate were separated and collected as shown in Step (B-5) in FIG. 2. 40 liters of agglomerate were collected. In this way, the silicon component was removed, and the cerium oxide component was concentrated.

### Polishing Agent Recycling Process

### Adjustment of pH Value and Electrical Conductivity Value

Maleic acrylate copolymer as a dispersing agent was added to the above polishing agent slurry, and the electrical conductivity value was adjusted to equal to that of the reference polishing agent slurry 1. Furthermore, the pH value of the polishing agent slurry was adjusted to 5.5 by using an acetic acid aqueous solution as a pH raising agent.

### Particle Diameter Control

After that, after stirring with a stirrer for 30 minutes, the agglomerate was dispersed and loosened using an ultrasonic dispersing machine (manufactured by Branson).

After the dispersion was completed, filtration was performed using a depth filter of a pore diameter of 10 μm to obtain recycled polishing agent slurry 1 including recycled cerium oxide. The obtained recycled polishing agent slurry 1 was 50 liters, with a cerium oxide concentration of 10.0% by mass and a particle diameter (D 90) of less than 2.0 μm. The pH value, electrical conductivity (relative value), and particle diameter (D50) of the obtained final recycled polishing agent slurry are shown in Table I.

The recycled polishing agent slurry 1 was prepared in this way.

### Preparation of Recycled Polishing Agent Slurries 2 to 20 and 22 to 25

Recycled polishing agent slurries 2 to 20 and 22 to 25 were prepared in the same manner as the preparation of the recycled polishing agent slurry 1, except that the amounts of dispersing agent, pH adjusting agent, and collected slurry liquid were adjusted such that the pH values, electrical conductivity ratio, and collected slurry liquid amount were those shown in Table I. The electrical conductivity ratio is the value (relative value) of the electrical conductivity of the recycled polishing agent slurry when the electrical conductivity value of the reference polishing agent slurry 1 is taken as 1.00 (reference value).

When adjustments were made to increase the pH (to alkalinity), ammonia water was used.

### Preparation of Recycled Polishing Agent Slurry 21

Recycled polishing agent slurry 21 was prepared using the recycled polishing agent slurry 7. That is, after the polishing process in the same manner as the preparation of the recycled polishing agent slurry 1 except that the recycled polishing agent slurry 7 prepared above was used instead of the reference polishing agent slurry 1, 1000 liters of collected slurry liquid was obtained. Then, the recycled polishing agent slurry 21 was prepared in the same manner as the preparation of the recycled polishing agent slurry 1 except that the amounts of the dispersing agent and pH adjusting agent were adjusted in the separation and concentration process and in the polishing agent recycling process such that the pH value and the electrical conductivity in Table I were obtained. That is, the recycled polishing agent slurry 7 was prepared based on the reference polishing agent slurry 1, and the recycled polishing agent slurry 21 was prepared after further polishing process using this recycled polishing agent slurry 7. The recycled polishing agent slurry was prepared by repeating the recycling process twice from the reference polishing agent slurry 1.

The electrical conductivity ratio of the recycled polishing agent slurry 21 shown in Table I is the value (relative value) of the electrical conductivity of the recycled polishing agent slurry 21 when the electrical conductivity value of the recycled polishing agent slurry 1 is taken as 1.00 (reference value).

The mass ratio of the additives to the glass component was calculated by the measurement method described above.

### Evaluation of Recycled Polishing Agent Slurry

### Measurement of Polishing Rate

### Measurement of Polishing Rate of Reference Polishing Agent Slurry 1

Using the polishing machine illustrated in FIG. 1, 50 liters of the above-prepared reference polishing agent slurry 1 was supplied to the surface to be polished while the surface to be polished was polished with a polishing cloth. The polishing process was performed while the reference polishing agent slurry 1 was supplied in circulation at a flow rate of 5 L/min. The object to be polished was an aluminosilicate glass substrate with a diameter of 65 mm, and the polishing cloth was made of polyurethane. The pressure applied to the surface to be polished during polishing was set to 9.8 kPa (100 g/cm²), and the rotation rate of the polishing testing machine was set at 100 min⁻¹ (rpm), and the polishing process was performed for 30 minutes.

After the polishing process using the slurry was performed for 30 minutes, the supply of the slurry to the polishing machine was stopped and instead pure water was supplied to wash the aluminosilicate glass substrate, and then the glass substrate was taken out of the polishing machine.

A new aluminosilicate glass substrate was newly installed in the polishing machine and the polishing process was performed in the same manner. The polishing process was performed for 10 batches each including 70 substrates, that is, for a total of 700 pieces.

The thickness of each glass substrate was measured before and after the polishing using Digimicro MF501 (manufactured by Nikon Corporation). Based on the difference in thickness before and after the polishing, the polishing amount (μm) per minute was calculated. The arithmetic mean (additive mean) of the polishing rates (μm/min) of all glass substrates was calculated. This was used as the reference value (1.00), and the following criteria were used for evaluation.

### Measurement of Polishing Rate of Recycled Polishing Agent Slurries 1 to 25

Polishing rates of the recycled polishing agent slurries 1 to 25 were measured in the same manner as above, and relative polishing rates thereof were calculated with respect to the polishing rate (the reference value, 1.0) of the reference polishing agent slurry 1. The following criteria were used for evaluation.

AA: Relative polishing rate was 0.95 or more with respect to the reference polishing agent slurry 1.

BB: Relative polishing rate was 0.90 or more and less than 0.95 with respect to the reference polishing agent slurry 1.

CC: Relative polishing rate was less than 0.90 with respect to the reference polishing agent slurry 1.

Scratches and burns were evaluated visually on all 350 pieces of glass after the polishing process.

### Evaluation of Scratches

For the evaluation of scratches, the surface of each glass after the polishing process was irradiated with a condensing lamp in a darkened room and was visually checked. When scratches were visually observed on the surface, the glass was evaluated as good. When scratches were visually observed on the glass surface, the glass was assumed to be good. When no scratches were visually observed on the glass surface, the glass was assumed to be defective. For evaluation, a ratio of the number of scratches generated in response to the polishing process using the recycled polishing agent slurry was calculated with respect to the reference number of scratches generated in response to the polishing process using the reference polishing agent slurry 1.

AA: Ratio of the number of scratches was 1.0 or less with respect to the reference polishing agent slurry 1.

BB: Ratio of the number of scratches was more than 1.0 and 1.2 or less with respect to the reference polishing agent slurry 1.

CC: Ratio of the number of scratches was more than 1.2 with respect to the reference polishing agent slurry 1.

### Evaluation of Burns

For the evaluation of burns such as “white burns” or “blue bums”, the glass after the polishing process was visually checked. When burns were not visually observed, the glass was assumed to be good. When burns were visually observed, the glass was assumed to be defective. For evaluation, a ratio of the number of burns generated in response to the polishing process using the recycled polishing agent slurry was calculated with respect to the reference number of burns generated in response to the polishing process using the reference polishing agent slurry 1.

AA: Ratio of the number of burns was 1.0 or less with respect to the reference polishing agent slurry 1.

BB: Ratio of the number of burns was more than 1.0 and 1.2 or less with respect to the reference polishing agent slurry 1.

CC: Ratio of the number of burns was more than 1.2 with respect to the reference polishing agent slurry 1.

The results of the above evaluations are shown in Table I.

In the following table, dispersing agents and pH adjusting agents are abbreviated as follows.

Dispersing Agent 1: Maleic acrylate copolymer

Dispersing Agent 2: Ammonium polyacrylate

Dispersing Agent 3: Polyethyleneimine

pH Adjusting Agent 1: Acetic acid aqueous solution

pH Adjusting Agent 2: Ammonia water

pH Adjusting Agent 3: Nitric acid aqueous solution

pH Adjusting Agent 4: Sulfuric acid aqueous solution

pH Adjusting Agent 5: Triethanolamine

pH Adjusting Agent 6: Hydrochloric acid aqueous solution

pH Adjusting Agent 7: Citric acid aqueous solution

pH Adjusting Agent 8: Maleic acid aqueous solution

pH Adjusting Agent 9: Ethylenediaminetetraacetic acid aqueous solution

pH Adjusting Agent 10: Ethylenediaminetetraacetic acid. 2NH₄ aqueous solution

pH Adjusting Agent 11: Ethylenediaminetetraacetic acid. 2Na solution

pH Adjusting Agent 12: Ethidronic acid (HEDP) aqueous solution

pH Adjusting Agent 13: Sodium hydroxide aqueous solution

pH Adjusting Agent 14: Potassium hydroxide aqueous solution

pH Adjusting Agent 15: Glycol ether diamine tetraacetic acid aqueous solution

pH Adjusting Agent 16: 3 -hydroxy-2,2′-iminodisuccinate tetrasodium

In the following table, “reference polishing agent slurry 1” is abbreviated as “Reference 1” and “recycled polishing agent slurry 1” is abbreviated as “Recycled 1.” Other polishing agent slurries are abbreviated in the same manner.

Since the reference polishing agent slurry 1 (Reference 1) does not include a glass component, the value of the mass ratio of the dispersing material to the glass component (in the table, abbreviated as “mass ratio (additive/glass)”) is blank in the table.

TABLE I

| | Collected | | | | Electrical | | Particle | | | | |
|---|---|---|---|---|---|---|---|---|---|---|---|
| Polishing | Slurry | | pH | | Conduc- | Mass Ratio | Diameter | Evaluation | | | |
| Agent Slurry | Liquid | Dispersing | Adjusting | | tivity | (Additive/ | (D50) | Polishing | | | |
| No. | Amount[L] | Agent | Agent | pH | Ratio | Glass) | [μM] | Rate | Scratch | Burn | Remarks |
| Reference 1 | Reference | 1 | 2 | 8.5 | 1.00 | | 0.96 | Reference | Reference | Reference | Reference |
| Recycled 1 | 1000 | 1 | 1 | 5.5 | 1.00 | 54.2 | 1.50 | CC | CC | BB | Comparative |
| | | | | | | | | | | | Example |
| Recycled 2 | 1000 | 1 | 1 | 6.0 | 1.00 | 54.1 | 1.09 | BB | BB | BB | Present |
| | | | | | | | | | | | Invention |
| Recycled 3 | 1000 | 1 | 1 | 6.5 | 1.00 | 54.0 | 0.95 | BB | BB | AA | Present |
| | | | | | | | | | | | Invention |
| Recycled 4 | 1000 | 1 | 1 | 7.0 | 1.00 | 54.0 | 0.90 | AA | BB | AA | Present |
| | | | | | | | | | | | Invention |
| Recycled 5 | 1000 | 1 | 1 | 7.5 | 1.00 | 54.0 | 0.93 | AA | BB | AA | Present |
| | | | | | | | | | | | Invention |
| Recycled 6 | 1000 | 1 | 2 | 8.0 | 1.00 | 54.0 | 0.87 | AA | AA | AA | Present |
| | | | | | | | | | | | Invention |
| Recycled 7 | 1000 | 1 | 2 | 8.5 | 1.00 | 54.0 | 0.90 | AA | AA | AA | Present |
| | | | | | | | | | | | Invention |
| Recycled 8 | 1000 | 1 | 2 | 9.0 | 1.00 | 54.1 | 0.91 | AA | AA | AA | Present |
| | | | | | | | | | | | Invention |
| Recycled 9 | 1000 | 1 | 2 | 9.5 | 1.00 | 54.2 | 0.85 | AA | AA | AA | Present |
| | | | | | | | | | | | Invention |
| Recycled 10 | 1000 | 1 | 2 | 10.0 | 1.00 | 54.6 | 0.80 | AA | AA | AA | Present |
| | | | | | | | | | | | Invention |
| Recycled 11 | 1000 | 1 | 2 | 10.5 | 1.00 | 55.9 | 0.79 | BB | AA | BB | Present |
| | | | | | | | | | | | Invention |
| Recycled 12 | 1000 | 1 | 2 | 11.0 | 1.00 | 54.4 | 0.81 | BB | AA | CC | Comparative |
| | | | | | | | | | | | Example |
| Recycled 13 | 1000 | 1 | 2 | 11.5 | 1.00 | 55.4 | 0.78 | BB | AA | CC | Comparative |
| | | | | | | | | | | | Example |
| Recycled 14 | 1000 | 1 | 2 | 12.0 | 1.00 | 58.3 | 0.75 | CC | AA | CC | Comparative |
| | | | | | | | | | | | Example |
| Recycled 15 | 1000 | 1 | 2 | 8.5 | 0.10 | 5.4 | 1.11 | BB | BB | AA | Present |
| | | | | | | | | | | | Invention |
| Recycled 16 | 1000 | 1 | 2 | 8.5 | 0.50 | 27.0 | 0.92 | AA | AA | AA | Present |
| | | | | | | | | | | | Invention |
| Recycled 17 | 1000 | 1 | 2 | 8.5 | 1.50 | 81.0 | 0.85 | AA | AA | AA | Present |
| | | | | | | | | | | | Invention |
| Recycled 18 | 1000 | 1 | 2 | 8.5 | 2.00 | 108.0 | 0.81 | AA | AA | AA | Present |
| | | | | | | | | | | | Invention |
| Recycled 19 | 1000 | 1 | 2 | 8.5 | 5.00 | 270.0 | 0.79 | AA | AA | AA | Present |
| | | | | | | | | | | | Invention |
| Recycled 20 | 1000 | 1 | 2 | 8.5 | 10.00 | 539.9 | 0.80 | BB | AA | BB | Present |
| | | | | | | | | | | | Invention |
| Recycled 21 | 1000 | 1 | 2 | 8.5 | 1.00 | 51.4 | 0.88 | AA | AA | AA | Present |
| | | | | | | | | | | | Invention |
| Recycled 22 | 750 | 1 | 2 | 8.5 | 1.00 | 4.1 | 0.87 | AA | AA | AA | Present |
| | | | | | | | | | | | Invention |
| Recycled 23 | 500 | 1 | 2 | 8.5 | 1.00 | 2.7 | 0.98 | AA | AA | AA | Present |
| | | | | | | | | | | | Invention |
| Recycled 24 | 200 | 1 | 2 | 8.5 | 1.00 | 1.1 | 0.93 | AA | AA | AA | Present |
| | | | | | | | | | | | Invention |
| Recycled 25 | 150 | 1 | 2 | 8.5 | 1.00 | 0.8 | 1.12 | BB | AA | AA | Present |
| | | | | | | | | | | | Invention |

Table I shows that the recycled polishing agent slurry obtained by the preparation method of the present invention results in less reduction of polishing rate and less occurrence of scratches and burns.

### Example 2

The following is an example of the preparation method of recycled polishing agent slurry using the filter filtration method in the separation and concentration process. Unless otherwise noted, the preparation of the polishing agent slurry was basically conducted under the conditions of 25° C. and 55% RH. At this time, the temperature of the solution and the like is also 25° C.

### Preparation of Reference Polishing Agent Slurry 101

Ammonium polyacrylate was added to pure water as a dispersing agent, and the mixture was stirred with a stirrer for 5 minutes. After that, cerium oxide (E21, Mitsui Mining & Smelting Co., Ltd.) was added while stirring, and after stirring with a stirrer for 30 minutes, dispersion was carried out with an ultrasonic dispersing machine (manufactured by Branson).

Cerium oxide was added such that its concentration was 10% by mass, and the dispersing agent was added such that its ratio with respect to cerium oxide was 5% by mass. The polishing agent slurry was prepared so that the total volume was 50 liters.

After that, the pH and electrical conductivity values of the prepared reference polishing agent slurry 101 were measured under the respective conditions described above. Subsequently, the pH value was adjusted to 8.5 using ammonia water as a pH adjusting agent. After that, the particle diameter (D50) was measured by the method described above.

The following measurement devices were used.

pH value: Lakom tester tabletop-type pH meter (pH 1500 manufactured by asOne Co,.Ltd.)

Electrical conductivity value: Compact electrical conductivity meter LAQUAtwin B-771 (manufactured by HORIBA, Ltd.)

The particle diameter (D50) was 0.93 μm.

### Preparation of Recycled Polishing Agent Slurry 101

A recycled polishing agent slurry 101 was prepared according to the following manufacturing process.

### Polishing Process

### Polishing

The polishing process of quartz glass substrates was carried out under the following conditions.

In the polishing process illustrated in FIG. 1, the unused reference polishing agent slurry 101 prepared as described above was used as the reference polishing agent slurry, and was supplied to a surface to be polished while the surface to be polished was polished with a polishing cloth. The polishing process was performed while the reference polishing agent slurry 101 was supplied in circulation at a flow rate of 5 L/min. The object to be polished was an quartz glass substrate with a diameter of 65 mm, and the polishing cloth was made of polyurethane. The pressure applied to the surface to be polished during polishing was set to 9.8 kPa (100 g/cm²), and the rotation rate of the polishing testing machine was set at 100 min⁻¹ (rpm), and the polishing process was performed for 10 minutes. The polishing process was performed for 10 batches each including 70 substrates, that is, for a total of 700 pieces.

The quartz glass substrate contained 99.9% by mass or more of silicon oxide and 0.1% by mass or less of other components.

### Slurry Collecting Process

After polishing was completed, the drained wash water including the polishing agent slurry and the polishing agent slurry including the used polishing agent were collected to obtain 1000 liters of collected slurry liquid.

### Separation and Concentration Process

The collected slurry liquid was first filtered using a cartridge filter with a pore diameter of 25 μm, and then filtered using a cartridge filter with a pore diameter of 10 μm to remove foreign matter.

Next, using the filter filtration device illustrated in FIG. 3, the solvent component of the slurry was removed. In the filter filtration device, “Cefilt” (pore diameter: 0.5 μm), a ceramic filter manufactured by NGK Insulators, was used as the filtration filter.

The solvent was removed until the slurry became 50 liters.

### Polishing Agent Recycling Process

### Adjustment of pH Value and Electrical Conductivity Value

Ammonium polyacrylate as a dispersing agent was added to the above polishing agent slurry, and the electrical conductivity value was adjusted to equal to that of the reference polishing agent slurry 101. Furthermore, the pH value of the polishing agent slurry was adjusted to 5.5 by using a nitric acid aqueous solution as a pH raising agent.

### Particle Diameter Control

After that, stirring was performed with a stirrer for 30 minutes.

After that, filtration using a membrane filter with a pore diameter of 10 microns was performed to obtain a recycled polishing agent slurry including recycled cerium oxide. The obtained recycled polishing agent slurry was 52 liters, with a cerium oxide concentration of 10.0% by mass.

The pH value, electrical conductivity (relative value), and particle diameter (D50) of the obtained final recycled polishing agent slurry 101 are shown in Table II.

The recycled polishing agent slurry 101 was prepared in this way.

### Preparation of Recycled Polishing Agent Slurries 102 to 120 and 122 to 125

Recycled polishing agent slurries 102 to 120 and 122 to 125 were prepared in the same manner as the preparation of the recycled polishing agent slurry 101, except that the amounts of dispersing agent, pH adjusting agent, and collected slurry liquid were adjusted such that the pH values, electrical conductivity ratio, and collected slurry liquid amount were those shown in Table II. The electrical conductivity ratio is the value (relative value) of the electrical conductivity of the recycled polishing agent slurry when the electrical conductivity value of the reference polishing agent slurry 101 is taken as 1.00 (reference value).

When adjustments were made to increase the pH (to alkalinity), ammonia water was used.

### Preparation of Recycled Polishing Agent Slurry 121

Recycled polishing agent slurry 121 was prepared using the recycled polishing agent slurry. That is, after the polishing process in the same manner as the preparation of the recycled polishing agent slurry 101 except that the recycled polishing agent slurry 107 prepared above was used instead of the reference polishing agent slurry 101, 1000 liters of collected slurry liquid was obtained. Then, the recycled polishing agent slurry 121 was prepared in the same manner as the preparation of the recycled polishing agent slurry 101 except that the amounts of the dispersing agent and pH adjusting agent were adjusted in the separation and concentration process and in the polishing agent recycling process such that the pH value and the electrical conductivity in Table II were obtained. That is, the recycled polishing agent slurry 107 was prepared based on the reference polishing agent slurry 101, and the recycled polishing agent slurry 123 was prepared after further polishing process using this recycled polishing agent slurry 107. The recycled polishing agent slurry 121 was prepared by repeating the recycling process twice from the reference polishing agent slurry 101.

The electrical conductivity ratio of the recycled polishing agent slurry 121 is the value (relative value) of the electrical conductivity of the recycled polishing agent slurry 121 when the electrical conductivity value of the recycled polishing agent slurry 101 is taken as 1.00 (reference value).

The mass ratio of the additives to the glass component was calculated by the measurement method described above.

### Evaluation of Recycled Polishing Agent Slurry

### Measurement of Polishing Rate

### Measurement of Polishing Rate of Reference Polishing Agent Slurry 101

Using the polishing machine illustrated in FIG. 1, 50 liters of the above-prepared reference polishing agent slurry 101 was supplied to the surface to be polished while the surface to be polished was polished with a polishing cloth. The polishing process was performed while the reference polishing agent slurry 101 was supplied in circulation at a flow rate of 5 L/min. The object to be polished was a quartz glass substrate with a diameter of 65 mm, and the polishing cloth was made of polyurethane. The pressure applied to the surface to be polished during polishing was set to 9.8 kPa (100 g/cm²), and the rotation rate of the polishing testing machine was set at 100 min⁻¹ (rpm), and the polishing process was performed for 10 minutes.

After the polishing process using the polishing agent slurry was performed for 10 minutes, the supply of the slurry to the polishing machine was stopped and instead pure water was supplied to wash the quartz glass substrate, and then the quartz glass substrate was taken out of the polishing machine.

A new quartz glass substrate was newly installed in the polishing machine and the polishing process was performed in the same manner. The polishing process was performed for 20 batches each including 35 substrates, that is, for a total of 700 pieces.

The thickness of each quartz glass substrate was measured before and after the polishing using Digimicro MF501 (manufactured by Nikon Corporation). Based on the difference in thickness before and after the polishing, the polishing amount (μm) per minute was calculated. The arithmetic mean (additive mean) of the polishing rates (μm/min) of all glass substrates was calculated. This was used as the reference value (1.00), and the following criteria were used for evaluation.

### Measurement of Polishing Rate of Recycled Polishing Agent Slurries 101 to 125

Polishing rates of the recycled polishing agent slurries 101 to 125 were measured in the same manner as above, and relative polishing rates thereof were calculated with respect to the polishing rate (the reference value 1.00) of the reference polishing agent slurry 101. The following criteria were used for evaluation.

AA: Relative polishing rate was 0.95 or more with respect to the reference polishing agent slurry 101.

BB: Relative polishing rate was 0.90 or more and less than 0.95 with respect to the reference polishing agent slurry 101.

CC: Relative polishing rate was less than 0.90 with respect to the reference polishing agent slurry 101.

Scratches and burns were evaluated visually on all 350 pieces of glass after the polishing process.

### Evaluation of Scratches

For the evaluation of scratches, the surface of each glass after the polishing process was irradiated with a condensing lamp in a darkened room and was visually checked. When scratches were visually observed on the surface, the glass was evaluated as good. When scratches were visually observed on the glass surface, the glass was assumed to be good. When no scratches were visually observed on the glass surface, the glass was assumed to be defective. For evaluation, a ratio of the number of scratches generated in response to the polishing process using the recycled polishing agent slurry was calculated with respect to the reference number of scratches generated in response to the polishing process using the reference polishing agent slurry 101.

AA: Ratio of the number of scratches was 1.0 or less with respect to the reference polishing agent slurry 101.

BB: Ratio of the number of scratches was more than 1.0 and 1.2 or less with respect to the reference polishing agent slurry 101.

CC: Ratio of the number of scratches was more than 1.2 with respect to the reference polishing agent slurry 101.

### Evaluation of Burns

For the evaluation of burns such as “white burns” or “blue burns”, the glass after the polishing process was visually checked. When burns were not visually observed, the glass was assumed to be good. When burns were visually observed, the glass was assumed to be defective. For evaluation, a ratio of the number of burns generated in response to the polishing process using the recycled product was calculated with respect to the reference number of burns generated in response to the polishing process using the reference polishing agent slurry 101.

AA: Ratio of the number of burns was 1.0 or less with respect to the reference polishing agent slurry 101.

BB: Ratio of the number of burns was more than 1.0 and 1.2 or less with respect to the reference polishing agent slurry 101.

CC: Ratio of the number of burns was more than 1.2 with respect to the reference polishing agent slurry 101.

The results of the above evaluations are shown in Table II.

Since the reference polishing agent slurry 101 (Reference 101) does not include a glass component, the value of the mass ratio of the dispersing material to the glass component (in the table, abbreviated as “additive/glass mass ratio”) is blank in the table.

TABLE II

| | Collected | | | | Electrical | | Particle | | | | |
|---|---|---|---|---|---|---|---|---|---|---|---|
| Polishing | Slurry | | pH | | Conduc- | Mass Ratio | Diameter | Evaluation | | | |
| Agent Slurry | Liquid | Dispersing | Adjusting | | tivity | (Additive/ | (D50) | Polishing | | | |
| No. | Amount[L] | Agent | Agent | pH | Ratio | Glass) | [μm] | Rate | Scratch | Burn | Remarks |
| Reference 101 | Reference | 2 | 2 | 8.5 | 1.00 | | 0.93 | Reference | Reference | Reference | Reference |
| Recycled 101 | 1000 | 2 | 3 | 5.5 | 1.00 | 541.1 | 1.45 | CC | CC | AA | Comparative |
| | | | | | | | | | | | Example |
| Recycled 102 | 1000 | 2 | 3 | 6.0 | 1.00 | 541.1 | 1.12 | BB | BB | AA | Present |
| | | | | | | | | | | | Invention |
| Recycled 103 | 1000 | 2 | 3 | 6.5 | 1.00 | 541.1 | 0.93 | BB | BB | AA | Present |
| | | | | | | | | | | | Invention |
| Recycled 104 | 1000 | 2 | 3 | 7.0 | 1.00 | 541.1 | 0.89 | BB | AA | AA | Present |
| | | | | | | | | | | | Invention |
| Recycled 105 | 1000 | 2 | 3 | 7.5 | 1.00 | 541.1 | 0.90 | AA | BB | AA | Present |
| | | | | | | | | | | | Invention |
| Recycled 106 | 1000 | 2 | 2 | 8.0 | 1.00 | 541.2 | 0.92 | AA | AA | AA | Present |
| | | | | | | | | | | | Invention |
| Recycled 107 | 1000 | 2 | 2 | 8.5 | 1.00 | 541.3 | 0.86 | AA | AA | AA | Present |
| | | | | | | | | | | | Invention |
| Recycled 108 | 1000 | 2 | 2 | 9.0 | 1.00 | 541.7 | 0.82 | AA | AA | AA | Present |
| | | | | | | | | | | | Invention |
| Recycled 109 | 1000 | 2 | 2 | 9.5 | 1.00 | 543.1 | 0.88 | AA | AA | AA | Present |
| | | | | | | | | | | | Invention |
| Recycled 110 | 1000 | 2 | 2 | 10.0 | 1.00 | 547.3 | 0.80 | BB | AA | AA | Present |
| | | | | | | | | | | | Invention |
| Recycled 111 | 1000 | 2 | 2 | 10.5 | 1.00 | 560.6 | 0.75 | BB | AA | AA | Present |
| | | | | | | | | | | | Invention |
| Recycled 112 | 1000 | 2 | 2 | 11.0 | 1.00 | 545.5 | 0.75 | CC | AA | AA | Comparative |
| | | | | | | | | | | | Example |
| Recycled 113 | 1000 | 2 | 2 | 11.5 | 1.00 | 554.8 | 0.79 | CC | AA | AA | Comparative |
| | | | | | | | | | | | Example |
| Recycled 114 | 1000 | 2 | 2 | 12.0 | 1.00 | 584.4 | 0.72 | CC | AA | AA | Comparative |
| | | | | | | | | | | | Example |
| Recycled 115 | 1000 | 2 | 2 | 8.5 | 0.10 | 54.3 | 0.91 | BB | BB | AA | Present |
| | | | | | | | | | | | Invention |
| Recycled 116 | 1000 | 2 | 2 | 8.5 | 0.50 | 270.8 | 0.85 | AA | BB | AA | Present |
| | | | | | | | | | | | Invention |
| Recycled 117 | 1000 | 2 | 2 | 8.5 | 1.50 | 811.9 | 0.88 | AA | AA | AA | Present |
| | | | | | | | | | | | Invention |
| Recycled 118 | 1000 | 2 | 2 | 8.5 | 2.00 | 1082.4 | 0.81 | AA | AA | AA | Present |
| | | | | | | | | | | | Invention |
| Recycled 119 | 1000 | 2 | 2 | 8.5 | 5.00 | 2705.8 | 0.79 | AA | AA | AA | Present |
| | | | | | | | | | | | Invention |
| Recycled 120 | 1000 | 2 | 2 | 8.5 | 10.00 | 5411.4 | 0.75 | BB | AA | AA | Present |
| | | | | | | | | | | | Invention |
| Recycled 121 | 1000 | 2 | 2 | 8.5 | 1.00 | 515.5 | 0.84 | AA | AA | AA | Present |
| | | | | | | | | | | | Invention |
| Recycled 122 | 750 | 2 | 2 | 8.5 | 1.00 | 40.7 | 0.83 | AA | AA | AA | Present |
| | | | | | | | | | | | Invention |
| Recycled 123 | 500 | 2 | 2 | 8.5 | 1.00 | 27.2 | 0.88 | AA | AA | AA | Present |
| | | | | | | | | | | | Invention |
| Recycled 124 | 200 | 2 | 2 | 8.5 | 1.00 | 10.9 | 0.84 | AA | AA | AA | Present |
| | | | | | | | | | | | Invention |
| Recycled 125 | 150 | 2 | 2 | 8.5 | 1.00 | 8.1 | 0.94 | BB | AA | AA | Present |
| | | | | | | | | | | | Invention |

Table II shows that the recycled polishing agent slurry obtained by the preparation method of the present invention results in less reduction of polishing rate and less occurrence of scratches and burns.

### Example 3

The following is an example of the preparation method of recycled polishing agent slurry using the filter filtration method in the separation and concentration process. Unless otherwise noted, the preparation of the polishing agent slurry was basically conducted under the conditions of 25° C. and 55% RH. At this time, the temperature of the solution and the like is also 25° C.

### Preparation of Reference Polishing Agent Slurry 201

In Example 3, unlike Examples 1 and 2, recycled polishing agent slurry was used as the reference slurry. Specifically, in the preparation of recycled polishing agent material slurry 107 in Example 2, a quartz glass substrate was processed with the recycled polishing agent slurry 107. The dispersing agent to be added to the collected used polishing agent slurry was changed from ammonium polyacrylate to polyethyleneimine. The recycled polishing agent slurry was prepared by adding the dispersing agent at 5% by mass with respect to cerium oxide. This was used as the reference polishing agent slurry 201 for polishing an aluminosilicate glass substrate.

After that, the pH value was adjusted to 8.5 using triethanolamine as a pH adjusting agent. After that, the particle diameter (D50) was measured by the method described above.

The following measurement devices were used.

pH value: Lakom tester tabletop-type pH meter (pH 1500 manufactured by asOne Co,.Ltd.)

Electrical conductivity value: Compact electrical conductivity meter LAQUAtwin B-771 (manufactured by HORIBA, Ltd.)

The particle diameter (D50) was 0.99 μm.

### Preparation of Recycled Polishing Agent Slurry 201

A recycled polishing agent slurry 201 was prepared according to the following manufacturing process.

### Polishing Process

### Polishing

The polishing process of aluminosilicate glass substrates was carried out under the following conditions.

In the polishing process illustrated in FIG. 1, the reference polishing agent slurry 201 prepared as described above was used as the reference polishing agent slurry, and was supplied to a surface to be polished while the surface to be polished was polished with a polishing cloth. The polishing process was performed while the reference polishing agent slurry 201 was supplied in circulation at a flow rate of 5 L/min. The object to be polished was an aluminosilicate glass substrate with a diameter of 65 mm, and the polishing cloth was made of polyurethane. The pressure applied to the surface to be polished during polishing was set to 9.8 kPa (100 g/cm²), and the rotation rate of the polishing testing machine was set at 100 min⁻¹ (rpm), and the polishing process was performed for 30 minutes. The polishing process was performed for 10 batches each including 70 substrates, that is, for a total of 700 pieces.

Aluminosilicate glass substrate contained 60% by mass of silicon oxide, 15% by mass of oxides of an alkali metal and an alkaline earth metal, and 25% by mass of aluminum oxide and other components.

### Slurry Collecting Process

After polishing was completed, the drained wash water including the polishing agent slurry and the polishing agent slurry including the used polishing agent were collected to obtain 1000 liters of collected slurry liquid.

### Separation and Concentration Process

The collected slurry liquid was first filtered using a cartridge filter with a pore diameter of 25 μm, and then filtered using a cartridge filter with a pore diameter of 10 μm to remove foreign matter.

Next, while the collected slurry liquid was stirred to prevent the cerium oxide from sedimenting, 2.5 liters of a 1.0% by mass of magnesium chloride solution was added to the slurry solution over a period of 10 minutes. The pH value at 25° C. was 7.60 immediately after the magnesium chloride was added.

After 30 minutes of continuous stirring under the above conditions, the mixture was left still for 1.5 hours, and the supernatant liquid and the agglomerate were separated by sedimentation using the natural sedimentation method. After 1.5 hours, according to Step (B-4) in FIG. 2, the supernatant liquid was drained using a drain pump, and the agglomerate were separated and collected as shown in Step (B-5) in FIG. 2. 40 liters of agglomerate were collected. In this way, the silicon component was removed, and the cerium oxide component was concentrated.

### Polishing Agent Recycling Process

### Adjustment of pH Value and Electrical Conductivity Value

Polyethyleneimine as a dispersing agent was added to the above slurry, and the electrical conductivity value was adjusted to equal to that of the reference polishing agent slurry 201. Furthermore, the pH value of the polishing agent slurry was adjusted to 5.5 by using a sulfuric acid aqueous solution as a pH raising agent.

### Particle Diameter Control

After that, after stirring with a stirrer for 30 minutes, the agglomerate was dispersed and loosened using an ultrasonic dispersing machine (manufactured by Branson).

After the dispersion was completed, filtration was performed using a depth filter of a pore diameter of 10 μm to obtain recycled polishing agent slurry 201 including recycled cerium oxide. The obtained recycled polishing agent slurry 1 was 50 liters, with a cerium oxide concentration of 10.0% by mass and a particle diameter (D 90) of less than 2.0 μm.

The pH value, electrical conductivity (relative value), and particle diameter (D50) of the obtained final recycled polishing agent slurry 201 are shown in Table III.

The recycled polishing agent slurry 201 was prepared in this way.

### Preparation of Recycled Polishing Agent Slurries 202 to 220 and 222 to 236

Recycled polishing agent slurries 202 to 220 and 222 to 236 were prepared in the same manner as the preparation of the recycled polishing agent slurry 201, except that the amounts of dispersing agent, pH adjusting agent, and collected slurry liquid were adjusted such that the pH values, electrical conductivity ratio, and collected slurry liquid amount were those shown in Table III. The electrical conductivity ratio is the value (relative value) of the electrical conductivity of the recycled polishing agent slurry when the electrical conductivity value of the reference polishing agent slurry 201 is taken as 1.00 (reference value).

When adjustments were made to increase the pH (to alkalinity), triethanolamine was used.

### Preparation of Recycled Polishing Agent Slurry 221

Recycled polishing agent slurry 221 was prepared using the recycled polishing agent slurry 207. That is, after the polishing process in the same manner as the preparation of the recycled polishing agent slurry 201 except that the recycled polishing agent slurry 207 prepared above was used as the reference polishing agent slurry, 1000 liters of collected slurry liquid was obtained. Then, the recycled polishing agent slurry 221 was prepared in the same manner as the preparation of the recycled polishing agent slurry 201 except that the amounts of the dispersing agent and pH adjusting agent were adjusted in the separation and concentration process and in the polishing agent recycling process such that the pH value and the electrical conductivity in Table III were obtained.

That is, the recycled polishing agent slurry 207 was prepared based on the reference polishing agent slurry 201, and the recycled polishing agent slurry 221 was prepared after further polishing process using this recycled polishing agent slurry 207. The recycled polishing agent slurry was prepared by repeating the recycling process twice from the reference polishing agent slurry 201.

The electrical conductivity ratio of the recycled polishing agent slurry 223 is the value (relative value) of the electrical conductivity of the recycled polishing agent slurry 221 when the electrical conductivity value of the recycled polishing agent slurry 201 is taken as 1.00 (reference value).

The mass ratio of the additives to the glass component was calculated by the measurement method described above.

### Evaluation of Recycled Polishing Agent Slurry

### Measurement of Polishing Rate

### Measurement of Polishing Rate of Reference Polishing Agent Slurry 201

Using the polishing machine illustrated in FIG. 1, 50 liters of the above-prepared reference polishing agent slurry 201 was supplied to the surface to be polished while the surface to be polished was polished with a polishing cloth. The polishing process was performed while the reference polishing agent slurry 201 was supplied in circulation at a flow rate of 5 L/min. The object to be polished was an aluminosilicate glass substrate with a diameter of 65 mm, and the polishing cloth was made of polyurethane. The pressure applied to the surface to be polished during polishing was set to 9.8 kPa (100 g/cm²), and the rotation rate of the polishing testing machine was set at 100 min⁻¹ (rpm), and the polishing process was performed for 30 minutes.

After the polishing process using the slurry was performed for 30 minutes, the supply of the slurry to the polishing machine was stopped and instead pure water was supplied to wash the aluminosilicate glass substrate, and then the glass substrate was taken out of the polishing machine.

A new aluminosilicate glass substrate was newly installed in the polishing machine and the polishing process was performed in the same manner. The polishing process was performed for 10 batches each including 70 substrates, that is, for a total of 700 pieces.

The thickness of each glass substrate was measured before and after the polishing using Digimicro MF501 (manufactured by Nikon Corporation). Based on the difference in thickness before and after the polishing, the polishing amount (μm) per minute was calculated. The arithmetic mean (additive mean) of the polishing rates (μm/min) of all glass substrates was calculated. This was used as the reference value (1.00), and the following criteria were used for evaluation.

### Measurement of Polishing Rate of Recycled Polishing Agent Slurries 201 to 236

Polishing rates of the recycled polishing agent slurries 201 to 236 were measured in the same manner as above, and relative polishing rates thereof were calculated with respect to the polishing rate (the reference value, 1.00) of the reference polishing agent slurry 201. The following criteria were used for evaluation.

AA: Relative polishing rate was 0.95 or more with respect to the reference polishing agent slurry 201.

BB: Relative polishing rate was 0.90 or more and less than 0.95 with respect to the reference polishing agent slurry 201.

CC: Relative polishing rate was less than 0.90 with respect to the reference polishing agent slurry 201.

Scratches and burns were evaluated visually on all 350 pieces of glass after the polishing process.

### Evaluation of Scratches

For the evaluation of scratches, the surface of each glass after the polishing process was irradiated with a condensing lamp in a darkened room and was visually checked. When scratches were visually observed on the surface, the glass was evaluated as good. When scratches were visually observed on the glass surface, the glass was assumed to be good. When no scratches were visually observed on the glass surface, the glass was assumed to be defective. For evaluation, a ratio of the number of scratches generated in response to the polishing process using the recycled polishing agent slurry was calculated with respect to the reference number of scratches generated in response to the polishing process using the reference polishing agent slurry 201.

AA: Ratio of the number of scratches was 1.0 or less with respect to the reference polishing agent slurry 201.

BB: Ratio of the number of scratches was more than 1.0 and 1.2 or less with respect to the reference polishing agent slurry 201.

CC: Ratio of the number of scratches was more than 1.2 with respect to the reference polishing agent slurry 201.

### Evaluation of Burns

For the evaluation of burns such as “white burns” or “blue burns”, the glass after the polishing process was visually checked. When burns were not visually observed, the glass was assumed to be good. When burns were visually observed, the glass was assumed to be defective. For evaluation, a ratio of the number of burns generated in response to the polishing process using the recycled product was calculated with respect to the reference number of burns generated in response to the polishing process using the reference polishing agent slurry 201.

AA: Ratio of the number of burns was 1.0 or less with respect to the reference polishing agent slurry 201.

BB: Ratio of the number of burns was more than 1.0 and 1.2 or less with respect to the reference polishing agent slurry 201.

CC: Ratio of the number of burns was more than 1.2 with respect to the reference polishing agent slurry 201.

The results of the above evaluations are shown in Tables III and IV.

The reference polishing agent slurry 201 is, as noted in the remarks column, a reference polishing agent slurry and is also in the scope of the present invention.

TABLE III

| | Collected | | | | Electrical | | Particle | | | | |
|---|---|---|---|---|---|---|---|---|---|---|---|
| Polishing | Slurry | | pH | | Conduc- | Mass Ratio | Diameter | Evaluation | | | |
| Agent Slurry | Liquid | Dispersing | Adjusting | | tivity | (Additive/ | (D50) | Polishing | | | |
| No. | Amount[L] | Agent | Agent | pH | Ratio | Glass) | [μm] | Rate | Scratch | Burn | Remarks |
| Reference 201 | Reference | 3 | 5 | 8.5 | 1.00 | 60.3 | 0.99 | Reference | Reference | Reference | Reference |
| Recycled 201 | 1000 | 3 | 4 | 5.5 | 1.00 | 51.7 | 1.52 | CC | CC | BB | Comparative |
| | | | | | | | | | | | Example |
| Recycled 202 | 1000 | 3 | 4 | 6.0 | 1.00 | 51.7 | 1.03 | BB | BB | AA | Present |
| | | | | | | | | | | | Invention |
| Recycled 203 | 1000 | 3 | 4 | 6.5 | 1.00 | 51.7 | 0.97 | BB | AA | AA | Present |
| | | | | | | | | | | | Invention |
| Recycled 204 | 1000 | 3 | 4 | 7.0 | 1.00 | 51.7 | 0.93 | BB | AA | AA | Present |
| | | | | | | | | | | | Invention |
| Recycled 205 | 1000 | 3 | 4 | 7.5 | 1.00 | 51.7 | 0.88 | AA | BB | AA | Present |
| | | | | | | | | | | | Invention |
| Recycled 206 | 1000 | 3 | 5 | 8.0 | 1.00 | 51.8 | 0.85 | AA | AA | AA | Present |
| | | | | | | | | | | | Invention |
| Recycled 207 | 1000 | 3 | 5 | 8.5 | 1.00 | 52.1 | 0.86 | AA | AA | AA | Present |
| | | | | | | | | | | | Invention |
| Recycled 208 | 1000 | 3 | 5 | 9.0 | 1.00 | 53.2 | 0.88 | AA | AA | AA | Present |
| | | | | | | | | | | | Invention |
| Recycled 209 | 1000 | 3 | 5 | 9.5 | 1.00 | 56.5 | 0.82 | AA | AA | AA | Present |
| | | | | | | | | | | | Invention |
| Recycled 210 | 1000 | 3 | 5 | 10.0 | 1.00 | 67.1 | 0.80 | BB | AA | AA | Present |
| | | | | | | | | | | | Invention |
| Recycled 211 | 1000 | 3 | 5 | 10.5 | 1.00 | 100.4 | 0.78 | BB | AA | BB | Present |
| | | | | | | | | | | | Invention |
| Recycled 212 | 1000 | 3 | 5 | 11.0 | 1.00 | 52.1 | 0.72 | CC | AA | BB | Comparative |
| | | | | | | | | | | | Example |
| Recycled 213 | 1000 | 3 | 5 | 11.5 | 1.00 | 53.0 | 0.74 | CC | AA | CC | Comparative |
| | | | | | | | | | | | Example |
| Recycled 214 | 1000 | 3 | 5 | 12.0 | 1.00 | 55.8 | 0.70 | CC | AA | CC | Comparative |
| | | | | | | | | | | | Example |
| Recycled 215 | 1000 | 3 | 5 | 8.5 | 0.10 | 5.7 | 1.20 | BB | BB | AA | Present |
| | | | | | | | | | | | Invention |
| Recycled 216 | 1000 | 3 | 5 | 8.5 | 0.50 | 26.3 | 0.93 | AA | BB | AA | Present |
| | | | | | | | | | | | Invention |
| Recycled 217 | 1000 | 3 | 5 | 8.5 | 1.50 | 78.0 | 0.88 | AA | AA | AA | Present |
| | | | | | | | | | | | Invention |
| Recycled 218 | 1000 | 3 | 5 | 8.5 | 2.00 | 103.8 | 0.81 | AA | AA | AA | Present |
| | | | | | | | | | | | Invention |
| Recycled 219 | 1000 | 3 | 5 | 8.5 | 5.00 | 258.8 | 0.79 | AA | AA | AA | Present |
| | | | | | | | | | | | Invention |
| Recycled 220 | 1000 | 3 | 5 | 8.5 | 10.00 | 517.0 | 0.75 | BB | AA | AA | Present |
| | | | | | | | | | | | Invention |
| Recycled 221 | 1000 | 3 | 5 | 8.5 | 1.00 | 51.8 | 0.86 | AA | AA | AA | Present |
| | | | | | | | | | | | Invention |
| Recycled 222 | 750 | 3 | 5 | 8.5 | 1.00 | 4.2 | 0.89 | AA | AA | AA | Present |
| | | | | | | | | | | | Invention |
| Recycled 223 | 500 | 3 | 5 | 8.5 | 1.00 | 2.8 | 0.95 | AA | AA | AA | Present |
| | | | | | | | | | | | Invention |
| Recycled 224 | 200 | 3 | 5 | 8.5 | 1.00 | 1.1 | 1.00 | BB | AA | AA | Present |
| | | | | | | | | | | | Invention |
| Recycled 225 | 150 | 3 | 5 | 8.5 | 1.00 | 0.8 | 1.32 | BB | AA | AA | Present |
| | | | | | | | | | | | Invention |

TABLE IV

| | Collected | | | | Electrical | | Particle | | | | |
|---|---|---|---|---|---|---|---|---|---|---|---|
| Polishing | Slurry | | pH | | Conduc- | Mass Ratio | Diameter | Evaluation | | | |
| Agent Slurry | Liquid | Dispersing | Adjusting | | tivity | (Additive/ | (D50) | Polishing | | | |
| No. | Amount[L] | Agent | Agent | pH | Ratio | Glass) | [μm] | Rate | Scratch | Burn | Remarks |
| Recycled 226 | 1000 | 2 | 6 | 6.5 | 1.00 | 53.99 | 0.87 | AA | BB | AA | Present |
| | | | | | | | | | | | Invention |
| Recycled 227 | 1000 | 2 | 7 | 6.5 | 1.00 | 54.06 | 0.92 | AA | AA | AA | Present |
| | | | | | | | | | | | Invention |
| Recycled 228 | 1000 | 2 | 8 | 6.5 | 1.00 | 53.99 | 0.85 | AA | AA | AA | Present |
| | | | | | | | | | | | Invention |
| Recycled 229 | 1000 | 2 | 9 | 6.5 | 1.00 | 54.09 | 0.88 | AA | AA | AA | Present |
| | | | | | | | | | | | Invention |
| Recycled 230 | 1000 | 2 | 10 | 6.5 | 1.00 | 65.13 | 0.81 | AA | AA | AA | Present |
| | | | | | | | | | | | Invention |
| Recycled 231 | 1000 | 2 | 11 | 6.5 | 1.00 | 66.70 | 0.98 | AA | BB | AA | Present |
| | | | | | | | | | | | Invention |
| Recycled 232 | 1000 | 2 | 12 | 6.5 | 1.00 | 53.99 | 0.85 | AA | AA | BB | Present |
| | | | | | | | | | | | Invention |
| Recycled 233 | 1000 | 2 | 13 | 8.0 | 1.00 | 53.99 | 1.01 | BB | AA | BB | Present |
| | | | | | | | | | | | Invention |
| Recycled 234 | 1000 | 2 | 14 | 8.0 | 1.00 | 53.99 | 1.05 | BB | AA | BB | Present |
| | | | | | | | | | | | Invention |
| Recycled 235 | 1000 | 2 | 15 | 7.5 | 1.00 | 183.86 | 0.94 | AA | AA | AA | Present |
| | | | | | | | | | | | Invention |
| Recycled 236 | 1000 | 2 | 16 | 8.0 | 1.00 | 54.75 | 0.89 | AA | AA | AA | Present |
| | | | | | | | | | | | Invention |

Tables III and IV show that the recycled polishing agent slurry obtained by the preparation method of the present invention results in less reduction of polishing rate and less occurrence of scratches and burns.

What is claimed is:

1. A preparation method of a recycled polishing agent slurry from a used polishing agent slurry after polishing a material to be polished whose main component is silicon using a reference polishing agent slurry including a cerium oxide polishing agent and a dispersing agent, the preparation method comprising:
slurry collecting in which the used polishing agent slurry discharged from a polishing machine is collected;
separation and concentration in which the cerium oxide polishing agent in the used polishing agent slurry that has been collected is separated from a component derived from the material to be polished and then concentrated, and
polishing agent recycling in which a pH adjusting agent and the dispersing agent are added to the cerium oxide polishing agent that has been separated and concentrated, and a recycled polishing agent slurry is adjusted to have a pH value at 25° C. of in a range of 6.0 to 10.5 and an electrical conductivity value in a range of 0.10 to 10.00 times that of the reference polishing agent slurry.

2. The preparation method of the recycled polishing agent slurry according to claim 1, wherein the reference polishing agent slurry is an unused polishing agent slurry.

3. The preparation method of the recycled polishing agent slurry according to claim 1, wherein the dispersing agent includes at least one of a water-soluble anionic dispersing agent, a water-soluble cationic dispersing agent, and a water-soluble amphoteric dispersing agent.

4. The preparation method of the recycled polishing agent slurry according to claim 1, wherein, in the separation and concentration, the cerium oxide polishing agent is separated from the component derived from the material to be polished and concentrated by filtration using a filter.

5. The preparation method of the recycled polishing agent slurry according to claim 1, wherein, in the separation and concentration, a divalent alkaline earth metal salt as an inorganic salt is added to the used polishing agent slurry that has been collected at a pH value at 25° C. in a range of 6.5 or more and less than 10.0, such that the cerium oxide polishing agent is separated from the component derived from the material to be polished and is concentrated.

6. The preparation method of the recycled polishing agent slurry according to claim 5, wherein the divalent alkaline earth metal salt is a magnesium salt.

7. The preparation method of the recycled polishing agent slurry according to claim 1, wherein the pH adjusting agent includes at least one of an inorganic acid, a carboxylic acid, an amine salt, and ammonium hydroxide.

8. A polishing agent slurry comprising:
an additive consisting of a dispersing agent and a pH adjusting agent;
a cerium oxide polishing agent; and
a glass component,
wherein the polishing agent slurry has a pH value at 25° C. in a range of 6.0 to 10.5, and
a mass ratio of the additive to the glass component is in a range of 0.8 to 5500.
